(19) United States
(12) Patent Application Publication
(10) Pub. No.: US 2012/0021190 A1
(43) Pub. Date: Jan. 26, 2012

(54) PHOTOSENSITIVE RESIN COMPOSITION, METHOD FOR FORMING SILICA COATING FILM, AND APPARATUS AND MEMBER EACH COMPRISING SILICA COATING FILM

(76) Inventors: Yousuke Aoki, Ibaraki (JP); Kouichi Abe, Ibaraki (JP); Kei Kasuya, Ibaraki (JP)

(21) Appl. No.: 13/125,426

(22) PCT Filed: Mar. 16, 2009
(86) PCT No.: PCT/JP2009/055029

§ 371 Date: Jul. 27, 2011

(30) Foreign Application Priority Data
Oct. 21, 2008 (JP) 2008-271207

(51) Int. Cl. G03F 7/20; B32B 3/10; G03F 7/004

(52) U.S. Cl. 428/195.1; 430/270.1; 430/326

(57) ABSTRACT

The photosensitive resin composition of the invention comprises component (a): a first siloxane resin obtained by hydrolytic condensation of a first silane compound comprising a compound represented by the following formula (1), component (b): a solvent in which component (a) dissolves, and component (c): an ester of a phenol or alcohol and naphthoquinone diazide sulfonic acid.

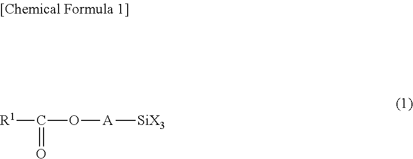

### TECHNICAL FIELD

The present invention relates to a photosensitive resin composition, to a method for forming a silica coating film, and to a semiconductor device, flat display device or electronic device member comprising a silica coating film formed by the method.

### BACKGROUND ART

Interlayer insulating films are used in the fabrication of flat display devices such as liquid crystal display devices, and semiconductor devices. Interlayer insulating films commonly have patterns formed by etching through a photoresist onto a film formed by accumulation or coating from a gas phase. Gas phase etching is usually employed when a fine pattern is to be formed. However, gas phase etching entails high equipment cost and has slow throughput.

Photosensitive materials for interlayer insulating films have therefore been developed with the aim of cost reduction. Photosensitive materials for interlayer insulating films having positive-type photosensitive properties are in demand particularly for liquid crystal display devices, because of the need to form contact holes in the interlayer insulating film for insulation between the picture element electrodes and the gate/drain wiring and for flattening of the device. Interlayer insulating films in liquid crystal display devices must also be transparent. Moreover, a film with low permittivity is desired when the patterned film is to remain on the interlayer insulating film for use.

Patent documents 1 and 2, for example, disclose methods for forming interlayer insulating films that have been proposed toward meeting these demands. Patent document 1 discloses a method for forming an interlayer insulating film comprising a step of forming a coating film of a photosensitive polysilazane composition comprising polysilazane and a photoacid generator, a step of irradiating light onto the coating film in a pattern, and a step of removing the irradiated sections of the coating film by dissolution. Also, Patent document 2 discloses an interlayer insulating film formed from a composition comprising a siloxane resin and a quinone diazide compound.
[Patent document 1] Japanese Unexamined Patent Application Publication No. 2000-181069
[Patent document 2] Japanese Unexamined Patent Application Publication No. 2006-178436

### SUMMARY OF INVENTION

### Technical Problem

When the film described in Patent document 1 is used as an interlayer insulating film, the polysilazane must be hydrolyzed to convert the polysilazane structure to a polysiloxane structure. If the film lacks moisture, hydrolysis will not proceed to a sufficient degree. Moreover, since highly volatile ammonia is generated during hydrolysis of the polysilazane, corrosion of the production apparatus is another problem.

The interlayer insulating film described in Patent document 2, which is formed from a composition comprising a siloxane resin and a quinone diazide compound, is associated with the problem of insufficient heat resistance.

It is therefore an object of the present invention to provide a photosensitive resin composition that allows relatively easy formation of a silica coating film which is usable as an interlayer insulating film, the silica coating film having excellent heat resistance and resolution, as well as a method for forming a silica coating film that employs the same. It is another object of the invention to provide a semiconductor device, flat display device or electronic device member comprising a silica coating film formed by the method.

### Solution to Problem

In order to achieve the aforestated objects, the invention provides a photosensitive resin composition comprising component (a): a first siloxane resin obtained by hydrolytic condensation of a first silane compound comprising a compound represented by the following formula (1), component (b): a solvent in which component (a) dissolves and component (c): an ester of a phenol or alcohol and naphthoquinone diazide sulfonic acid.

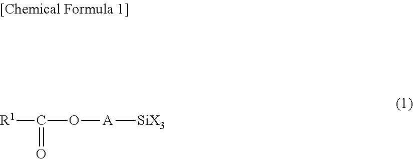

[In formula (1), R¹ represents an organic group, A represents a divalent organic group, and X represents a hydrolyzable group, where the multiple X groups in the same molecule may be the same or different.]

Since a siloxane resin is used in this photosensitive resin composition, it is possible to eliminate the step of converting the polysilazane structure to a polysiloxane structure, which is necessary in the method described in Patent document 1, and therefore a silica coating film can be formed more easily.

The silica coating film formed from the photosensitive resin composition also has excellent heat resistance and resolution. Although the reason for this effect by the silica coating film formed from the photosensitive resin composition of the invention is not fully understood, the present inventors conjecture as follows.

That is, it is believed that using a siloxane resin with excellent heat resistance in the photosensitive resin composition of the invention results in the excellent heat resistance of the silica coating film that is formed. Also, since the compound represented by formula (1) has an acyloxy group with high solubility in aqueous alkali solution, the first siloxane resin obtained by hydrolysis thereof also has high solubility in aqueous alkali solution. It is therefore easier to dissolve the exposed sections in an aqueous alkali solution during development after the exposure for formation of the silica coating film, such that the difference in solubilities of the unexposed sections and unexposed sections for the aqueous alkali solution increases, thereby increasing the resolution.

By comprising an ester of a phenol or alcohol and naphthoquinone diazide sulfonic acid as component (c), the photosensitive resin composition of the invention can exhibit satisfactory positive photosensitivity, and excellent developability can be obtained in the development after exposure for formation of the silica coating film.

Component (c) in the photosensitive resin composition of the invention preferably includes an ester of a phenol or an alcohol with one or more aryl groups, and naphthoquinone diazide sulfonic acid. This improves the photosensitive property of the silica coating film formed from the photosensitive resin composition.

The photosensitive resin composition of the invention preferably further comprises component (d): a second siloxane resin obtained by hydrolytic condensation of a second silane compound not comprising a compound represented by formula (1) above but comprising a compound represented by the following formula (2).

[Chemical Formula 2]

R²ₙSiX₄₋ₙ (2)

[In formula (2), R² represents an H atom or an organic group, X represents a hydrolyzable group and n represents an integer of 0-3, with the proviso that when n is 2 or smaller the multiple X groups in the same molecule may be the same or different, and when n is 2 or 3 the multiple R² groups in the same molecule may be the same or different.]

Thus, in the photosensitive resin composition of the invention it is preferred to use a combination of the (a) first siloxane resin with (d) a second siloxane compound different from the (a) first siloxane resin, whereby the silica coating film that is formed can provide excellent adhesion with substrates, and silica coating films with satisfactory shapes can be obtained without deterioration of the pattern shapes after curing.

The first silane compound in the photosensitive resin composition of the invention preferably further comprises a compound represented by the following formula (3). This further increases the heat resistance of the silica coating film formed from the photosensitive resin composition.

[Chemical Formula 3]

R³SiX₃ (3)

[In formula (3), R³ represents an organic group, and X represents a hydrolyzable group, where the multiple X groups in the same molecule may be the same or different.]

Component (b) in the photosensitive resin composition of the invention preferably comprises at least one solvent selected from the group consisting of ether acetate-based solvents, ether-based solvents, ester-based solvents, alcohol-based solvents and ketone-based solvents. This can help prevent coating unevenness and cissing when the photosensitive resin composition is coated onto a substrate.

The invention further provides a method for forming a silica coating film, which comprises a coating step in which the photosensitive resin composition of the invention described above is coated onto a substrate and dried to obtain a coating film, a first exposure step in which prescribed sections of the coating film are exposed, a removal step in which the prescribed sections of the coating film that have been exposed are removed, and a heating step in which the coating film from which the prescribed sections have been removed is heated. According to this forming method, which uses a photosensitive resin composition of the invention as described above, it is possible to obtain a silica coating film with excellent heat resistance and resolution.

The invention still further provides a method for forming a silica coating film, which comprises a coating step in which the photosensitive resin composition of the invention described above is coated onto a substrate and dried to obtain a coating film, a first exposure step in which prescribed sections of the coating film are exposed, a removal step in which the prescribed sections of the coating film that have been exposed are removed, a second exposure step in which the coating film from which the prescribed sections have been removed is exposed, and a heating step in which the coating film from which the prescribed sections have been removed is heated. According to this forming method, which uses a photosensitive resin composition as described above, it is possible to obtain a silica coating film with excellent heat resistance and resolution. Also, component (c) having optical absorption in the visible light range is decomposed in the second exposure step, thus producing a compound with sufficiently low optical absorption in the visible light range. The resulting silica coating film therefore has increased transparency.

The invention still further provides a semiconductor device, flat display device and electronic device member each comprising a substrate and a silica coating film formed on the substrate by the formation method of the invention described above. The semiconductor device, flat display device and electronic device member exhibit excellent performance since they are provided with a silica coating film from a photosensitive resin composition of the invention as described above, as an interlayer insulating film.

### Advantageous Effects of Invention

The invention can provide a photosensitive resin composition that allows relatively easy formation of a silica coating film which is usable as an interlayer insulating film, the formed silica coating film having excellent heat resistance and resolution, as well as a method for forming a silica coating film that employs the same. A silica coating film formed from the photosensitive resin composition of the invention also has excellent crack resistance, insulating properties, low dielectricity, and in some cases transparency. The invention can further provide a semiconductor device, flat display device and electronic device member each comprising a silica coating film formed by the method for forming a silica coating film described above.

### BRIEF DESCRIPTION OF DRAWINGS

FIG. 1 is a schematic cross-sectional view showing an embodiment of an electronic part of the invention.

FIG. 2 is a plan view showing the structure of one picture element section in an active matrix substrate for an embodiment of a flat display device of the invention.

FIG. 3 is a cross-sectional view of the active matrix substrate of FIG. 2 along III-III′.

### EXPLANATION OF SYMBOLS

1: Silicon wafer, 1A, 1B: diffusion regions, 2A: field oxide film, 2B: gate insulating film, 3: gate electrode, 4A, 4B: side wall oxide films, 5, 7: interlayer insulating films, 5A, 7A: contact holes, 6: bit line, 8A: storage electrode, 8B: capacitor insulating film, 8C: counter electrode, 10: memory cell capacitor, 21: picture element electrode, 22: gate wiring, 23: source wiring, 24: TFT, 25: connecting electrode, 26: contact hole, 31: transparent insulating board, 32: gate electrode, 36a: source electrode, 36b: drain electrode, 37a, 37b: transparent conductive films, 38a, 38b: metal layers, 39: interlayer insulating film.

### DESCRIPTION OF EMBODIMENTS

Preferred embodiments of the invention will now be explained in detail, with reference to the accompanying drawings as necessary. However, the present invention is not limited to the embodiments described below. Identical or corresponding parts in the drawings will be referred to by like reference numerals and will be explained only once.

The weight-average molecular weights referred to throughout the present specification were measured by gel permeation chromatography (hereinafter, “GPC”) and calculated using a standard polystyrene calibration curve.

The weight-average molecular weight (Mw) can be measured by GPC under the following conditions, for example.

### (Conditions)

### Sample: 10 μL

Standard polystyrene: Standard polystyrene by Tosoh Corp. (molecular weights: 190,000, 17,900, 9100, 2980, 578, 474, 370, 266).
Detector: RI-monitor by Hitachi, Ltd., trade name: “L-3000”
Integrator: GPC integrator by Hitachi, Ltd., trade name: “D-2200”
Pump: trade name: “L-6000”, by Hitachi, Ltd.
Degassing apparatus: Trade name “Shodex DEGAS” by Showa Denko K.K.
Column: Trade names “GL-R440”, “GL-R430” and “GL-R420” by Hitachi Chemical Co., Ltd., linked in that order.

### Eluent: Tetrahydrofuran (THF)

Measuring temperature: 23° C.
Flow rate: 1.75 mL/min
Measuring time: 45 minutes

### (Photosensitive Resin Composition)

The photosensitive resin composition of the invention comprises component (a), component (b) and component (c). Each of these components will now be explained.

<Component (a)>

Component (a) is a siloxane resin obtained by hydrolytic condensation of a silane compound (first silane compound) comprising a compound represented by the following formula (1).

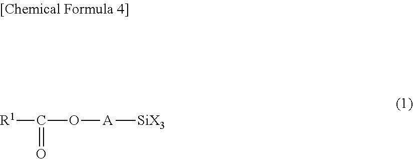

[In formula (1), R¹ represents an organic group, A represents a divalent organic group, and X represents a hydrolyzable group. Each X group may be the same or different.]

From the viewpoint of further improving the storage stability of the obtained photosensitive resin composition, component (a) is preferably used after washing. That is, preferably a solution of component (a) dissolved in a hydrophobic organic solvent is washed by agitated mixing with water. The washing is preferably carried out until the pH of the aqueous phase reaches 5.0-7.0.

Examples for the organic group represented by R¹ in formula (1) include aliphatic hydrocarbon and aromatic hydrocarbon groups. Preferred among these are C1-20 straight-chain, branched or cyclic aliphatic hydrocarbon groups. Specific examples of C1-20 straight-chain aliphatic hydrocarbon groups include groups such as methyl, ethyl, n-propyl, n-butyl and n-pentyl. Specific examples of branched aliphatic hydrocarbon groups include groups such as isopropyl and isobutyl. Specific examples of cyclic aliphatic hydrocarbon groups include groups such as cyclopentyl, cyclohexyl, cycloheptylene, norbornyl and adamantyl. Of these, C1-5 straight-chain hydrocarbon groups such as methyl, ethyl and propyl are more preferred, and methyl is especially preferred from the viewpoint of starting material availability.

Examples for the divalent organic group represented by A in formula (1) include divalent aromatic hydrocarbon and divalent aliphatic hydrocarbon groups; C1-20 straight-chain, branched and cyclic divalent hydrocarbon groups are preferred among these from the viewpoint of starting material availability.

Preferred specific examples of C1-20 straight-chain divalent hydrocarbon groups include groups such as methylene, ethylene, propylene, butylene and pentylene. Preferred specific examples of C1-20 branched divalent hydrocarbon groups include groups such as isopropylene and isobutylene. Preferred specific examples of C1-20 cyclic divalent hydrocarbon groups include groups such as cyclopentylene, cyclohexylene, cycloheptylene, groups with norbornane skeletons and groups with adamantane skeletons. Of these, C1-7 straight-chain divalent hydrocarbon groups such as methylene, ethylene and propylene, C3-7 cyclic divalent hydrocarbon groups such as cyclopentylene and cyclohexylene, and cyclic divalent hydrocarbon groups with norbornane skeletons are particularly preferred.

Examples for the hydrolyzable group represented by X in formula (1) include alkoxy, halogen atoms, acetoxy, isocyanate and hydroxyl groups. Of these, alkoxy groups are preferred from the standpoint of the liquid stability and coating characteristics of the photosensitive resin composition itself. For compounds represented by formulas (2) and (3) mentioned below as well, specific examples of hydrolyzable groups for X include the same groups as for X in the compounds represented by formula (1).

The first silane compound preferably further comprises a compound represented by the following formula (3). This further increases the heat resistance of the obtained silica coating film.

[Chemical Formula 5]

R³SiX₃ (3)

[In formula (3), R³ represents an organic group, and X represents a hydrolyzable group, where the multiple X groups in the same molecule may be the same or different.]

Examples for the organic group represented by R³ in formula (3) include aliphatic hydrocarbon and aromatic hydrocarbon groups. Preferred aliphatic hydrocarbon groups are C1-20 straight-chain, branched or cyclic aliphatic hydrocarbon groups. Specific examples of C1-20 straight-chain aliphatic hydrocarbon groups include groups such as methyl, ethyl, n-propyl, n-butyl and n-pentyl. Specific examples of branched aliphatic hydrocarbon groups include groups such as isopropyl and isobutyl. Specific examples of cyclic aliphatic hydrocarbon groups include groups such as cyclopentyl, cyclohexyl, cycloheptylene, norbornyl and adamantyl. Methyl, ethyl, propyl, norbornyl and adamantyl groups are more preferred among these from the viewpoint of thermal stability and starting material availability.

Preferred aromatic hydrocarbon groups are those with 6-20 carbon atoms. Specific examples include phenyl, naphthyl, anthracenyl, phenanthrenyl and pyrenyl. Phenyl and naphthyl groups are preferred among these from the viewpoint of thermal stability and starting material availability.

When the first silane compound includes a compound represented by formula (3) above, the content ratio is preferably 10-90 mass % and more preferably 30-80 mass %, with respect to the entire first silane compound.

In addition, the first silane compound may contain silane compounds other than compounds represented by formulas (1) and (3). Such silane compounds include, for example, compounds represented by formula (2) wherein n is 0 or 2. The content ratio of silane compounds other than compounds represented by formulas (1) and (3) in the first silane compound may be 0-50 mass %, for example, with respect to the entire first silane compound.

When the first silane compound is to be subjected to hydrolytic condensation, the compound represented by formula (1) may be of a single type alone or a combination of two or more. Similarly, the compound represented by formula (3) may also be of a single type alone or a combination of two or more. Likewise, the silane compounds other than compounds represented by formulas (1) and (3) may be of a single type alone or a combination of two or more.

A specific example of the structure of a siloxane resin (silsesquioxane) obtained by hydrolytic condensation of a silane compound containing a compound represented by formula (1) and a compound represented by formula (3) is represented by the following formula (4). This concrete example is the structure of a siloxane resin obtained by hydrolytic condensation of one type of compound represented by formula (1) (wherein R¹ is a methyl group) and two types of compounds represented by formula (3) (wherein R³ is a phenyl and methyl group, respectively). The subscript “3/2” indicates that O atoms are bonded in a ratio of 3/2 on each Si atom.

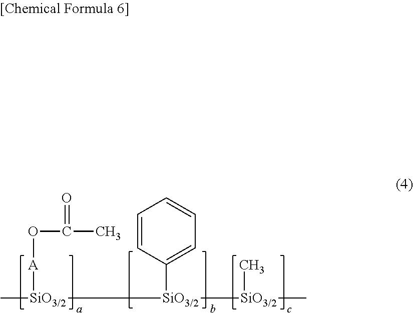

In formula (4), a, b and c each represent molar ratios (molar percentages) of the starting materials corresponding to each position, where a is 0.5-99, b is 0.5-99 and c is 0.5-99. The total of a, b and c is 100. In formula (4), A represents a divalent organic group.

Hydrolytic condensation of the first silane compound may be carried out under the following conditions, for example.

First, the amount of water used for hydrolytic condensation is preferably 0.01-1000 mol and more preferably 0.05-100 mol, per 1 mol of the compound represented by formula (1). If the amount of water is at least 0.01 mol the hydrolytic condensation reaction will tend to proceed sufficiently, while if the amount of water is no greater than 1000 mol, production of gelled substances during hydrolysis or during condensation will tend to be inhibited.

A catalyst may also be used for the hydrolytic condensation. Examples of such catalysts that may be used include acid catalysts, alkali catalysts and metal chelate compounds. Acid catalysts are preferred from the viewpoint of preventing hydrolysis of the acyloxy groups in the compound represented by formula (1).

Examples of acid catalysts include organic acids and inorganic acids. Examples of organic acids include formic acid, maleic acid, fumaric acid, phthalic acid, malonic acid, succinic acid, tartaric acid, malic acid, lactic acid, citric acid, acetic acid, propionic acid, butanoic acid, pentanoic acid, hexanoic acid, heptanoic acid, octanoic acid, nonanoic acid, decanoic acid, oxalic acid, adipic acid, sebacic acid, butyric acid, oleic acid, stearic acid, linolic acid, linoleic acid, salicylic acid, benzenesulfonic acid, benzoic acid, p-aminobenzoic acid, p-toluenesulfonic acid, methanesulfonic acid, trifluoromethanesulfonic acid and trifluoroethanesulfonic acid. Examples of inorganic acids include hydrochloric acid, phosphoric acid, nitric acid, boric acid, sulfuric acid and hydrofluoric acid. These may be used alone or in combinations of two or more.

The amount of such catalysts used is preferably in the range of 0.0001-1 mol with respect to 1 mole of the compound represented by formula (1). An amount of at least 0.0001 mol will tend to allow the reaction to proceed, while an amount of no greater than 1 mol will tend to inhibit gelling during hydrolytic condensation.

When the catalyst has been used in the hydrolytic condensation, the stability of the obtained photosensitive resin composition may be impaired, or the presence of the catalyst can potentially result in corrosion of other materials. Such adverse effects can be eliminated, for example, by removing the catalyst from the photosensitive resin composition after hydrolytic condensation, or by reacting the catalyst with another compound to inactivate the function of the catalyst. The method for accomplishing such procedures may be publicly known methods. For example, the catalyst may be removed by distillation or by an ion chromatographic method. The method of inactivating the function of the catalyst by reaction with another compound, when the catalyst is an acid catalyst, for example, may be a method of adding a base for neutralization by acid-base reaction.

Alcohol is also produced as a by-product during the hydrolytic condensation. Since such an alcohol is a protic solvent and can adversely affect the physical properties of the photosensitive resin composition, it is preferably removed using an evaporator or the like.

From the viewpoint of the solvent solubility and moldability, the first siloxane resin obtained in the manner described above preferably has a weight-average molecular weight of 500-1,000,000, more preferably 500-500,000, even more preferably 500-100,000 and yet more preferably 500-50,000. A weight-average molecular weight of at least 500 will tend to result in adequate film formability of the silica coating film, while a weight-average molecular weight of no greater than 1,000,000 will tend to ensure sufficient compatibility with solvents.

From the viewpoint of solubility in solvents, film thickness, moldability and solution stability, the mixing proportion of component (a) is preferably 5-50 mass % based on the total solid portion of the photosensitive resin composition. Since a greater mixing proportion is preferred from the viewpoint of film formability of the silica coating film, it is preferably at least 7 mass %, more preferably at least 10 mass % and most preferably at least 15 mass %. From the viewpoint of solution stability, it is also preferably no greater than 40 mass % and most preferably no greater than 35 mass %.

Since the photosensitive resin composition of the invention comprises component (a), the silica coating film that is formed exhibits excellent heat resistance and resolution. In addition, the excellent flexibility of component (a) in the photosensitive resin composition prevents cracking during heat treatment of the formed silica coating film, and thus results in excellent crack resistance. Because the formed silica coating film has excellent crack resistance, use of the photosensitive resin composition of the invention allows the silica coating film thickness to be increased.

<Component (d)>

Component (d) is a second siloxane resin obtained by hydrolytic condensation of a silane compound (second silane compound) comprising a compound represented by the following formula (2). In the photosensitive resin composition of the invention it is preferred to use a combination of the (a) first siloxane resin and the (d) second siloxane resin that is different from the (a) first siloxane resin. By using a combination of component (a) and component (d), it is possible to further improve the adhesion of the formed silica coating film with substrates, and to retain pattern shapes after curing.

[Chemical Formula 7]

R²ₙSiX₄₋ₙ (2)

[In formula (2), R² represents an H atom or an organic group, X represents a hydrolyzable group and n represents an integer of 0-3, with the proviso that when n is 2 or smaller the multiple X groups in the same molecule may be the same or different, and when n is 2 or 3 the multiple R² groups in the same molecule may be the same or different.]

From the viewpoint of further improving the storage stability of the obtained photosensitive resin composition, component (d) is also preferably used after washing. That is, preferably a solution of component (d) dissolved in a hydrophobic organic solvent is washed by agitated mixing with water. The washing is preferably carried out until the pH of the aqueous phase reaches 5.0-7.0.

Examples for the organic group represented by R² in formula (2) include amino groups, aromatic rings, groups with amino or epoxy groups, alicyclic hydrocarbons, and C1-20 alkyl groups. From the viewpoint of adhesion there are preferred groups with amino or epoxy groups, and methyl groups.

Examples of compounds represented by formula (2) wherein the hydrolyzable group represented by X in formula (2) is an alkoxy group (alkoxysilanes) include tetraalkoxysilanes, trialkoxysilanes and diorganodialkoxysilanes.

Examples of tetraalkoxysilanes include tetramethoxysilane, tetraethoxysilane, tetra-n-propoxysilane, tetraisopropoxysilane, tetra-n-butoxysilane, tetra-sec-butoxysilane, tetra-tert-butoxysilane and tetraphenoxysilane.

Examples of trialkoxysilanes include trimethoxysilane, triethoxysilane, tripropoxysilane, fluorotrimethoxysilane, fluorotriethoxysilane, methyltrimethoxysilane, methyltriethoxysilane, methyltri-n-propoxysilane, methyltriisopropoxysilane, methyltri-n-butoxysilane, methyltriisobutoxysilane, methyltri-tert-butoxysilane, methyltriphenoxysilane, ethyltrimethoxysilane, ethyltriethoxysilane, ethyltri-n-propoxysilane, ethyltriisopropoxysilane, ethyltri-n-butoxysilane, ethyltriisobutoxysilane, ethyltri-tert-butoxysilane, ethyltriphenoxysilane, n-propyltrimethoxysilane, n-propyltriethoxysilane, n-propyltri-n-propoxysilane, n-propyltriisopropoxysilane, n-propyltri-n-butoxysilane, n-propyltriisobutoxysilane, n-propyltri-tert-butoxysilane, n-propyltriphenoxysilane, isopropyltrimethoxysilane, isopropyltriethoxysilane, isopropyltri-n-propoxysilane, isopropyltriisopropoxysilane, isopropyltri-n-butoxysilane, isopropyltriisobutoxysilane, isopropyltri-tert-butoxysilane, isopropyltriphenoxysilane, n-butyltrimethoxysilane, n-butyltriethoxysilane, n-butyltri-n-propoxysilane, n-butyltriisopropoxysilane, n-butyltri-n-butoxysilane, n-butyltriisobutoxysilane, n-butyltri-tert-butoxysilane, n-butyltriphenoxysilane, sec-butyltrimethoxysilane, sec-butyltriethoxysilane, sec-butyltri-n-propoxysilane, sec-butyltriisopropoxysilane, sec-butyltri-n-butoxysilane, sec-butyltriisobutoxysilane, sec-butyltri-tert-butoxysilane, sec-butyltriphenoxysilane, tert-butyltrimethoxysilane, tert-butyltriethoxysilane, tert-butyltri-n-propoxysilane, tert-butyltriisopropoxysilane, tert-butyltri-n-butoxysilane, tert-butyltriisobutoxysilane, tert-butyltri-tert-butoxysilane, tert-butyltriphenoxysilane, phenyltrimethoxysilane, phenyltriethoxysilane, phenyltri-n-propoxysilane, phenyltriisopropoxysilane, phenyltri-n-butoxysilane, phenyltriisobutoxysilane, phenyltri-tert-butoxysilane, phenyltriphenoxysilane, trifluoromethyltrimethoxysilane, pentafluoroethyltrimethoxysilane, 3,3,3-trifluoropropyltrimethoxysilane and 3,3,3-trifluoropropyltriethoxysilane.

Examples of diorganodialkoxysilanes include dimethyldimethoxysilane, dimethyldiethoxysilane, dimethyldi-n-propoxysilane, dimethyldiisopropoxysilane, dimethyldi-n-butoxysilane, dimethyldi-sec-butoxysilane, dimethyldi-tert-butoxysilane, dimethyldiphenoxysilane, diethyldimethoxysilane, diethyldiethoxysilane, diethyldi-n-propoxysilane, diethyldiisopropoxysilane, diethyldi-n-butoxysilane, diethyldi-sec-butoxysilane, diethyldi-tert-butoxysilane, diethyldiphenoxysilane, di-n-propyldimethoxysilane, di-n-propyldiethoxysilane, di-n-propyldi-n-propoxysilane, di-n-propyldiisopropoxysilane, di-n-propyldi-n-butoxysilane, di-n-propyldi-sec-butoxysilane, di-n-propyldi-tert-butoxysilane, di-n-propyldiphenoxysilane, diisopropyldimethoxysilane, diisopropyldiethoxysilane, diisopropyldi-n-propoxysilane, diisopropyldiisopropoxysilane, diisopropyldi-n-butoxysilane, diisopropyldi-sec-butoxysilane, diisopropyldi-tert-butoxysilane, diisopropyldiphenoxysilane, di-n-butyldimethoxysilane, di-n-butyldiethoxysilane, di-n-butyldi-n-propoxysilane, di-n-butyldiisopropoxysilane, di-n-butyldi-n-butoxysilane, di-n-butyldi-sec-butoxysilane, di-n-butyldi-tert-butoxysilane, di-n-butyldiphenoxysilane, di-sec-butyldimethoxysilane, di-sec-butyldiethoxysilane, di-sec-butyldi-n-propoxysilane, di-sec-butyldiisopropoxysilane, di-sec-butyldi-n-butoxysilane, di-sec-butyldi-sec-butoxysilane, di-sec-butyldi-tert-butoxysilane, di-sec-butyldiphenoxysilane, di-tert-butyldimethoxysilane, di-tert-butyldiethoxysilane, di-tert-butyldi-n-propoxysilane, di-tert-butyldiisopropoxysilane, di-tert-butyldi-n-butoxysilane, di-tert-butyldi-sec-butoxysilane, di-tert-butyldi-tert-butoxysilane, di-tert-butyldiphenoxysilane, diphenyldimethoxysilane, diphenyldiethoxysilane, diphenyldi-n-propoxysilane, diphenyldiisopropoxysilane, diphenyldi-n-butoxysilane, diphenyldi-sec-butoxysilane, diphenyldi-tert-butoxysilane, diphenyldiphenoxysilane, bis(3,3,3-trifluoropropyl)dimethoxysilane and methyl (3,3,3-trifluoropropyl)dimethoxysilane.

Examples of compounds represented by formula (2) wherein X is an alkoxy group and R² is a C1-20 alkyl group include those mentioned above, as well as bissilylalkanes such as bis(trimethoxysilyl)methane, bis(triethoxysilyl)methane, bis(tri-n-propoxysilyl)methane, bis(triisopropoxysilyl)methane, bis(trimethoxysilyl)ethane, bis(triethoxysilyl)ethane, bis(tri-n-propoxysilyl)ethane, bis(triisopropoxysilyl)ethane, bis(trimethoxysilyl)propane, bis(triethoxysilyl)propane, bis(tri-n-propoxysilyl)propane and bis(triisopropoxysilyl)propane.

Examples of compounds represented by formula (2) wherein X is an alkoxy group and R² is a group with an aromatic ring include those mentioned above, as well as bissilylbenzenes such as bis(trimethoxysilyl)benzene, bis(triethoxysilyl)benzene, bis(tri-n-propoxysilyl)benzene and bis(triisopropoxysilyl)benzene.

Examples of compounds represented by formula (2) wherein X is an alkoxy group and R² is a group with an amino group include 4-aminobutyltriethoxysilane, N-(2-aminoethyl)-3-aminoisobutylmethylmethoxysilane, (aminoethylaminomethyl)phenethyltrimethoxysilane, N-(2-aminoethyl)-3-aminopropylmethyldimethoxysilane, N-(2-aminoethyl)-3-aminopropyltrimethoxysilane, N-(6-aminohexyl)aminopropyltrimethoxysilane, 3-(m-aminophenoxy)propyltrimethoxysilane, aminophenyltrimethoxysilane, 3-aminopropylmethyldiethoxysilane, 3-aminopropyltriethoxysilane, 3-aminopropyltrimethoxysilane and 6-azidosulfonylhexyltriethoxysilane.

Examples of compounds represented by formula (2) wherein X is an alkoxy group and R² is a group with an epoxy group include 5,6-epoxyhexyltriethoxysilane, (3-glycidoxypropyl)methyldiethoxysilane, (3-glycidoxypropyl)methyldimethoxysilane and (3-glycidoxypropyl)trimethoxysilane.

Particularly preferred among such compounds represented by formula (2) from the viewpoint of adhesion are tetraethoxysilane, 3-aminopropyltriethoxysilane and (3-glycidoxypropyl)methyldiethoxysilane. From the same viewpoint, compounds wherein n is 0 are preferred, with tetraalkoxysilanes being especially preferred.

When the second silane compound is to be subjected to hydrolytic condensation, the compound represented by formula (2) may be of a single type alone or a combination of two or more.

Hydrolytic condensation of the second silane compound may be carried out under the following conditions, for example.

First, the amount of water used for hydrolytic condensation is preferably 0.01-1000 mol and more preferably 0.05-100 mol, per 1 mol of the compound represented by formula (2). If the amount of water is at least 0.01 mol the hydrolytic condensation reaction will tend to proceed sufficiently, while if the amount of water is no greater than 1000 mol, production of gelled substances during hydrolysis or during condensation will tend to be inhibited.

A catalyst may also be used for the hydrolytic condensation. Examples of such catalysts that may be used include acid catalysts, alkali catalysts and metal chelate compounds.

Examples of acid catalysts include organic acids and inorganic acids. Examples of organic acids include formic acid, maleic acid, fumaric acid, phthalic acid, malonic acid, succinic acid, tartaric acid, malic acid, lactic acid, citric acid, acetic acid, propionic acid, butanoic acid, pentanoic acid, hexanoic acid, heptanoic acid, octanoic acid, nonanoic acid, decanoic acid, oxalic acid, adipic acid, sebacic acid, butyric acid, oleic acid, stearic acid, linolic acid, linoleic acid, salicylic acid, benzenesulfonic acid, benzoic acid, p-aminobenzoic acid, p-toluenesulfonic acid, methanesulfonic acid, trifluoromethanesulfonic acid and trifluoroethanesulfonic acid. Examples of inorganic acids include hydrochloric acid, phosphoric acid, nitric acid, boric acid, sulfuric acid and hydrofluoric acid. These may be used alone or in combinations of two or more.

Examples of alkali catalysts include inorganic alkalis and organic alkalis. Examples of inorganic alkalis include sodium hydroxide, potassium hydroxide, rubidium hydroxide and cesium hydroxide. Examples of organic alkalis include pyridine, monoethanolamine, diethanolamine, triethanolamine, dimethylmonoethanolamine, monomethyldiethanolamine, ammonia, tetramethylammonium hydroxide, tetraethylammonium hydroxide, tetrapropylammonium hydroxide, methylamine, ethylamine, propylamine, butylamine, pentylamine, hexylamine, heptylamine, octylamine, nonylamine, decylamine, undecylamine, dodecylamine, cyclopentylamine, cyclohexylamine, N,N-dimethylamine, N,N-diethylamine, N,N-dipropylamine, N,N-dibutylamine, N,N-dipentylamine, N,N-dihexylamine, N,N-dicyclopentylamine, N,N-dicyclohexylamine, trimethylamine, triethylamine, tripropylamine, tributylamine, tripentylamine, trihexylamine, tricyclopentylamine and tricyclohexylamine. These may be used alone or in combinations of two or more.

Examples of metal chelate compounds include metal chelate compounds containing titanium, such as trimethoxy mono(acetylacetonato)titanium, triethoxy mono(acetylacetonato)titanium, tri-n-propoxy mono(acetylacetonato)titanium, tri-iso-propoxy mono(acetylacetonato)titanium, tri-n-butoxy mono(acetylacetonato)titanium, tri-sec-butoxy mono(acetylacetonato)titanium, tri-tert-butoxy mono(acetylacetonato)titanium, dimethoxy mono(acetylacetonato)titanium, diethoxy di(acetylacetonato)titanium, di-n-propoxy di(acetylacetonato)titanium, di-iso-propoxy di(acetylacetonato)titanium, di-n-butoxy di(acetylacetonato)titanium, di-sec-butoxy di(acetylacetonato)titanium, di-tert-butoxy di(acetylacetonato)titanium, monomethoxy tris(acetylacetonato)titanium, monoethoxy tris(acetylacetonato)titanium, mono-n-propoxy tris(acetylacetonato)titanium, mono-iso-propoxy tris(acetylacetonato)titanium, mono-n-butoxy tris(acetylacetonato)titanium, mono-sec-butoxy tris(acetylacetonato)titanium, mono-tert-butoxy tris(acetylacetonato)titanium, tetrakis(acetylacetonato)titanium, trimethoxy mono(ethyl acetoacetate)titanium, triethoxy mono(ethyl acetoacetate)titanium, tri-n-propoxy mono(ethyl acetoacetate)titanium, tri-iso-propoxy mono(ethyl acetoacetate)titanium, tri-n-butoxy mono(ethyl acetoacetate)titanium, tri-sec-butoxy mono(ethyl acetoacetate)titanium, tri-tert-butoxy mono(ethyl acetoacetate)titanium, dimethoxy mono(ethyl acetoacetate)titanium, diethoxy di(ethyl acetoacetate)titanium, di-n-propoxy di(ethyl acetoacetate)titanium, di-iso-propoxy di(ethyl acetoacetate)titanium, di-n-butoxy di(ethyl acetoacetate)titanium, di-sec-butoxy di(ethyl acetoacetate)titanium, di-tert-butoxy di(ethyl acetoacetate)titanium, monomethoxy tris(ethyl acetoacetate)titanium, monoethoxy tris(ethyl acetoacetate)titanium, mono-n-propoxy tris(ethyl acetoacetate)titanium, mono-iso-propoxy tris(ethyl acetoacetate)titanium, mono-n-butoxy tris(ethyl acetoacetate)titanium, mono-sec-butoxy tris(ethyl acetoacetate)titanium, mono-tert-butoxy tris(ethyl acetoacetate)titanium and tetrakis(ethyl acetoacetate)titanium, and the aforementioned titanium-containing metal chelate compounds wherein the titanium has been replaced with zirconium, aluminum or the like. These may be used alone or in combinations of two or more.

The amount of such catalysts used is preferably in the range of 0.0001-1 mol with respect to 1 mole of the compound represented by formula (2). An amount of at least 0.0001 mol will tend to allow the reaction to proceed, while an amount of no greater than 1 mol will tend to inhibit gelling during hydrolytic condensation.

When a catalyst has been used in the hydrolytic condensation, the stability of the obtained photosensitive resin composition may be impaired, or the presence of the catalyst can potentially result in corrosion of other materials. Such adverse effects can be eliminated by, for example, removing the catalyst from the photosensitive resin composition after hydrolytic condensation, or by reacting the catalyst with another compound to inactivate the function of the catalyst. The methods for accomplishing such procedures may be publicly known methods. For example, the catalyst may be removed by distillation or by an ion chromatographic method. The method of inactivating the function of the catalyst by reaction with another compound, when the catalyst is an acid catalyst, for example, may be a method of adding a base for neutralization by acid-base reaction.

Alcohol is also produced as a by-product during the hydrolytic condensation. Since such an alcohol is a protic solvent and can adversely affect the physical properties of the photosensitive resin composition, it is preferably removed using an evaporator or the like.

From the viewpoint of the solvent solubility and moldability, the (d) second siloxane resin obtained in the manner described above preferably has a weight-average molecular weight of 500-1,000,000, more preferably 500-500,000, even more preferably 500-100,000 and yet more preferably 500-50,000. A weight-average molecular weight of at least 500 will tend to result in adequate film formability of the silica coating film, while a weight-average molecular weight of no greater than 1,000,000 will tend to ensure sufficient compatibility with solvents.

The mixing proportion of component (d) is preferably 0.01-80 mass %, more preferably 0.01-70 mass % and even more preferably 0.01-50 mass %, based on the total solid portion of the photosensitive resin composition. A mixing proportion of at least 0.01 mass % will tend to inhibit reduction in adhesion and deterioration of the pattern after curing, while a proportion of no greater than 80 mass % will tend to inhibit cracking in the film.

From the viewpoint of further improving the storage stability of the photosensitive resin composition, the (a) first siloxane resin, and the (d) second siloxane resin that may be used in combination therewith, have a pH in aqueous phase of preferably 5.0-7.0 and more preferably 6.0-7.0, when a solution of the siloxane resin in a hydrophobic organic solvent has been extracted with water.

As explained above, the pH may be adjusted by removing the acidic components, by extraction or washing of component (a) and component (d). If the pH of component (a) and component (d) is not excessively acidic or basic, i.e. if the pH is 5.0-7.0, condensation of the siloxane resin will be slowed and the storage stability of the photosensitive resin composition will tend to be improved.

Specifically, the pH of component (a) and component (d) is measured by adding an equivalent amount of a hydrophobic organic solvent (for example, methyl isobutyl ketone) to each component (a) and component (d) to prepare uniform solutions, and then adding ion-exchanged water at 50 parts by mass with respect to 100 parts by mass of the siloxane resin and measuring the pH of the aqueous phase produced after extraction. The pH of the aqueous phase is considered to correspond to the pH of the hydrophobic organic solvent solution (organic phase) containing component (a) or component (d). The final pH of the photosensitive resin composition of the invention is the value obtained by direct measurement using the photosensitive resin composition as a pH-measuring sample. The pH can be measured using a Model PH81 (trade name) by Yokogawa Electric Corp., under conditions of room temperature (24° C.), 50% relative humidity.

The hydrophobic organic solvent used may be methyl isobutyl ketone, methyl ethyl ketone, ethyl acetate, toluene, n-hexane, cyclohexane, xylene, diethyl ether or the like, with methyl isobutyl ketone being preferred.

<Component (e)>

The photosensitive resin composition of the invention may comprise a silane compound (third silane compound) having a hydrolyzable group represented by formula (2) above as component (e), if necessary in order to modify the adhesion of the formed silica coating film for substrates.

The (e) third silane compound may be the same type as the compounds represented by formula (2) in the second silane compound of component (d), and the same compounds are preferably used. Also, the (e) third silane compound may be a single type used alone, or a combination of two or more different ones. When both component (d) and component (e) are used in the photosensitive resin composition of the invention, the compound represented by formula (2) in component (d) and the (e) third silane compound may be the same or different.

When component (e) is added, its mixing proportion is preferably 0.01-50 mass %, more preferably 0.05-35 mass % and even more preferably 0.1-25 mass %, based on the total solid portion of the photosensitive resin composition, from the viewpoint of adhesion. If the mixing proportion is at least 0.01 mass % the adhesion will tend to be sufficient, and if it is no greater than 50 mass % the stability of the photosensitive resin composition will tend to be improved.

<Component (b)>

Component (b) is a solvent in which component (a) dissolves. Specific examples include aprotic solvents and protic solvents. These may be used alone or in combinations of two or more.

Examples of aprotic solvents include ketone-based solvents such as acetone, methyl ethyl ketone, methyl-n-propylketone, methyl-iso-propylketone, methyl-n-butylketone, methyl-iso-butylketone, methyl-n-pentylketone, methyl-n-hexylketone, diethylketone, dipropylketone, di-iso-butylketone, trimethylnonanone, cyclohexanone, cyclopentanone, methylcyclohexanone, 2,4-pentanedione, acetonylacetone, y-butyrolactone and y-valerolactone; ether-based solvents such as diethyl ether, methyl ethyl ether, methyldi-n-propyl ether, diisopropyl ether, tetrahydrofuran, methyltetrahydrofuran, dioxane, dimethyldioxane, ethyleneglycol dimethyl ether, ethyleneglycol diethyl ether, ethyleneglycol di-n-propyl ether, ethyleneglycol dibutyl ether, diethyleneglycol dimethyl ether, diethyleneglycol diethyl ether, diethyleneglycol methyl ethyl ether, diethyleneglycolmethyl mono-n-propyl ether, diethyleneglycolmethyl mono-n-butyl ether, diethyleneglycol di-n-propyl ether, diethyleneglycol di-n-butyl ether, diethyleneglycolmethyl mono-n-hexyl ether, triethyleneglycol dimethyl ether, triethyleneglycol diethyl ether, triethyleneglycol methyl ethyl ether, triethyleneglycolmethyl mono-n-butyl ether, triethyleneglycol di-n-butyl ether, triethyleneglycolmethyl mono-n-hexyl ether, tetraethyleneglycol dimethyl ether, tetraethyleneglycol diethyl ether, tetradiethyleneglycol methyl ethyl ether, tetraethyleneglycolmethyl mono-n-butyl ether, diethyleneglycol di-n-butyl ether, tetraethyleneglycolmethyl mono-n-hexyl ether, tetraethyleneglycol di-n-butyl ether, propyleneglycol dimethyl ether, propyleneglycol diethyl ether, propyleneglycol di-n-propyl ether, propyleneglycol dibutyl ether, dipropyleneglycol dimethyl ether, dipropyleneglycol diethyl ether, dipropyleneglycol methyl ethyl ether, dipropyleneglycolmethyl mono-n-butyl ether, dipropyleneglycol di-n-propyl ether, dipropyleneglycol di-n-butyl ether, dipropyleneglycolmethyl mono-n-hexyl ether, tripropyleneglycol dimethyl ether, tripropyleneglycol diethyl ether, tripropyleneglycol methyl ethyl ether, tripropyleneglycolmethyl mono-n-butyl ether, tripropyleneglycol di-n-butyl ether, tripropyleneglycolmethyl mono-n-hexyl ether, tetrapropyleneglycol dimethyl ether, tetrapropyleneglycol diethyl ether, tetradipropyleneglycol methyl ethyl ether, tetrapropyleneglycolmethyl mono-n-butyl ether, dipropyleneglycol di-n-butyl ether, tetrapropyleneglycolmethyl mono-n-hexyl ether and tetrapropyleneglycol di-n-butyl ether; ester-based solvents such as methyl acetate, ethyl acetate, n-propyl acetate, isopropyl acetate, n-butyl acetate, isobutyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, nonyl acetate, methyl acetoacetate, ethyl acetoacetate, diethyleneglycol monomethyl ether acetate, diethyleneglycol monoethyl ether acetate, diethyleneglycol mono-n-butyl ether acetate, dipropyleneglycol monomethyl ether acetate, dipropyleneglycol monoethyl ether acetate, glycol diacetate, methoxytriglycol acetate, ethyl propionate, n-butyl propionate, isoamyl propionate, diethyl oxalate and di-n-butyl oxalate; ether acetate-based solvents such as ethyleneglycol methyl ether propionate, ethyleneglycol ethyl ether propionate, ethyleneglycol methyl ether acetate, ethyleneglycol ethyl ether acetate, diethyleneglycol methyl ether acetate, diethyleneglycol ethyl ether acetate, diethylene glycol-n-butyl ether acetate, propyleneglycol methyl ether acetate, propyleneglycol ethyl ether acetate, propyleneglycol propyl ether acetate, dipropyleneglycol methyl ether acetate and dipropyleneglycol ethyl ether acetate; and acetonitrile, N-methylpyrrolidinone, N-ethylpyrrolidinone, N-propylpyrrolidinone, N-butylpyrrolidinone, N-hexylpyrrolidinone, N-cyclohexylpyrrolidinone, N,N-dimethylformamide, N,N-dimethylacetamide, N,N-dimethyl sulfoxide, toluene, xylene and the like. Preferred among these are ether-based solvents, ether acetate based solvents and ketone-based solvents, from the viewpoint of allowing increased thickness of the formed silica coating film and improving the solution stability of the photosensitive resin composition. Most preferred among these are ether acetate-based solvents, followed by ether-based solvents and ketone-based solvents, from the viewpoint of preventing coating unevenness and cissing. These may be used alone or in combinations of two or more.

Examples of protic solvents include alcohol-based solvents such as methanol, ethanol, n-propanol, isopropanol, n-butanol, isobutanol, sec-butanol, tert-butanol, n-pentanol, isopentanol, 2-methylbutanol, sec-pentanol, tert-pentanol, 3-methoxybutanol, n-hexanol, 2-methylpentanol, sec-hexanol, 2-ethylbutanol, sec-heptanol, n-octanol, 2-ethylhexanol, sec-octanol, n-nonyl alcohol, n-decanol, sec-undecyl alcohol, trimethylnonyl alcohol, sec-tetradecyl alcohol, sec-heptadecyl alcohol, phenol, cyclohexanol, methylcyclohexanol, benzyl alcohol, ethylene glycol, 1,2-propylene glycol, 1,3-butylene glycol, diethylene glycol, dipropylene glycol, triethylene glycol and tripropylene glycol; ether-based solvents such as ethyleneglycol methyl ether, ethyleneglycol ethyl ether, ethyleneglycol monophenyl ether, diethyleneglycol monomethyl ether, diethyleneglycol monoethyl ether, diethyleneglycol mono-n-butyl ether, diethyleneglycol mono-n-hexyl ether, ethoxytriglycol, tetraethyleneglycol mono-n-butyl ether, propyleneglycol monomethyl ether, dipropyleneglycol monomethyl ether, dipropyleneglycol monoethyl ether and tripropyleneglycol monomethyl ether; and ester-based solvents such as methyl lactate, ethyl lactate, n-butyl lactate and n-amyl lactate. Alcohol-based solvents are preferred among these from the viewpoint of storage stability. Ethanol, isopropyl alcohol and propyleneglycol propyl ether are preferred from the viewpoint of minimizing coating unevenness and cissing. These may be used alone or in combinations of two or more.

The type of component (b) may be appropriately selected depending on the types of component (a) and component (c). For example, when component (c) is an ester of naphthoquinone diazide sulfonic acid and a phenol, and the solubility in aliphatic hydrocarbon-based solvents is low, an aromatic hydrocarbon-based solvent such as toluene may be selected as appropriate.

The content of component (b) may be appropriately adjusted according to the type of component (a) and component (c), and for example, it may be 0.1-2000 parts by mass with respect to 100 parts by mass as the total solid portion of the photosensitive resin composition.

The method of adding component (b) to the photosensitive resin composition may be any known method. Specific examples include a method of its use as a solvent during preparation of component (a), a method of its addition after preparation of component (a), a method of solvent exchange, and a method of adding component (b) after component (a) has been removed by solvent removal or the like.

<Component (c)>

Component (c) is a naphthoquinone diazide sulfonic acid ester, which is an ester of a phenol or alcohol with naphthoquinone diazide sulfonic acid. This component is used to impart positive photosensitivity to the photosensitive resin composition. Positive photosensitivity is exhibited in the following manner, for example.

Specifically, the naphthoquinone diazide group in the naphthoquinone diazide sulfonic acid ester is originally not soluble in alkali developing solutions, and furthermore inhibits dissolution of the siloxane resin in alkali developing solutions. However, irradiation with ultraviolet rays or visible light converts the naphthoquinone diazide groups into an indenecarboxylic acid structure, so that high solubility in alkali developing solutions is exhibited. Thus, addition of component (c) imparts positive photosensitivity whereby the exposed sections are removed by the alkali developing solution.

The naphthoquinone diazide sulfonic acid ester as component (c) is an ester of naphthoquinone diazide sulfonic acid and a phenol or alcohol, and from the viewpoint of compatibility with component (c) and transparency (sensitivity) of the formed silica coating film, it preferably includes an ester of a naphthoquinone diazide sulfonic acid and a phenol or an alcohol with at least one aryl group.

Examples of naphthoquinone diazide sulfonic acids include naphthoquinone-1,2-diazide-5-sulfonic acid, naphthoquinone-1,2-diazide-4-sulfonic acid, and derivatives thereof.

Alcohols are monohydric and polyhydric alcohols, and preferred are those with one or more aryl groups.

Alcohols with 3 or more aryl groups are preferably dihydric or greater alcohols. This is because when 3 or more aryl groups are present, the proportion occupied by naphthoquinone diazide positions in the naphthoquinone diazide sulfonic acid ester molecule decreases, potentially lowering the photosensitive property.

Specific examples of phenols and alcohols with aryl groups include phenol, o-cresol, m-cresol, p-cresol, o-ethylphenol, p-ethylphenol, 2,3-xylenol, 2,5-xylenol, 2,6-xylenol, 3,4-xylenol, 3,5-xylenol, o-isopropylphenol, p-isopropylphenol, mesitol, o-propylphenol, m-propylphenol, p-propylphenol, 2,3,5-trimethylphenol, 2,3,6-trimethylphenol, 2,4,6-trimethylphenol, o-methoxyphenol, m-methoxyphenol, p-methoxyphenol, o-ethoxyphenol, m-ethoxyphenol, p-ethoxyphenol, 2-methoxy-4-methylphenol, 2-methoxy-5-methylphenol, 3-methoxy-5-methylphenol, salicylic acid, methyl salicylate, ethyl salicylate, isopropyl salicylate, isobutyl salicylate, 4-hydroxycoumarin, 7-hydroxycoumarin, benzyl alcohol, o-methylbenzyl alcohol, m-methylbenzyl alcohol, p-methylbenzyl alcohol, o-methoxybenzyl alcohol, m-methoxybenzyl alcohol, phenethyl alcohol, 2,5-dimethylbenzyl alcohol, 3,5-dimethylbenzyl alcohol, 1-(2-methylphenyl)ethanol, 1-(4-methylphenyl)ethanol, 2-phenoxyethanol, 2-(4-methylphenyl)ethanol, 2-(p-tolyl)ethanol, 1-phenyl-1-propanol, 2-phenyl-1-propanol, 2-phenyl-2-propanol, 3-phenyl-1-propanol, p-xylene-α,α′-diol, o-tert-butylphenol, m-tert-butylphenol, p-tert-butylphenol, p-sec-butylphenol, 6-tert-butyl-m-cresol, 2-tert-butyl-p-cresol, o-cyclohexylphenol, 2,4-di-tert-butylphenol, 2,6-di-tert-butylphenol, o-allylphenol, 2,6-diisopropylphenol, 2,4,6-trimethylphenol, 2-isopropyl-5-methylphenol, 4-isopropyl-3-methylphenol, 4-tert-butyl-2-methylphenol, 2-tert-butyl-6-methylphenol, catechol, resorcinol, hydroquinone, 2,3-dihydroxytoluene, 2,6-dihydroxytoluene, 3,4-dihydroxytoluene, 3,5-dihydroxytoluene, salicyl alcohol, o-hydroxybenzyl alcohol, m-hydroxybenzyl alcohol, p-hydroxybenzyl alcohol, 1,2-benzenedimethanol, 1,3-benzenedimethanol, 1,4-benzenedimethanol, 2,6-bis(hydroxymethyl)-p-cresol, 2,4-bis(hydroxymethyl)-m-cresol, 2,4,6-tris(hydroxymethyl)phenol, 1-naphthol, 2-naphthol, (1,3)-dihydroxynaphthalene, (1,4)-1-dihydroxynaphthalene, (1,5)-dihydroxynaphthalene, (1,6)-dihydroxynaphthalene, (2,3)-dihydroxynaphthalene, (2,6)-dihydroxynaphthalene, (2,7)-dihydroxynaphthalene, 1-naphthalenemethanol, 2-naphthalenemethanol, 7-methoxy-2-naphthol, 4-methoxy-1-naphthol, 1-(1-naphthyl)ethanol, 1-(2-naphthyl)ethanol, 2-(1-naphthyl)ethanol, 1,4-naphthalenedimethanol, 2,3-naphthalenedimethanol, 2-(2-naphthoxy)ethanol, 2-hydroxybiphenyl, 3-hydroxybiphenyl, 4-hydroxybiphenyl, 2-biphenylethanol, 4-biphenylmethanol, 2-benzylphenol, benzhydrol, 2-methyl-3-biphenylmethanol, 1,1-diphenylethanol, 2,2-diphenylethanol, 1-(4-biphenylyl)ethanol, 2,2-bis(4-hydroxy)propane, 1,3-diphenoxypropan-2-ol, p-cumylphenol, 2-(4-biphenylyl)-2-propanol, 4-(4-biphenyl)-2-butanol, (2,3)biphenyldiol, (2,2′)biphenyldiol, (4,4′)biphenyldiol, 3-phenoxybenzyl alcohol, 4-4′methylenediphenol, 2-benzyloxyphenol, 4-benzyloxyphenol, 1,2-diphenyl-1,2-ethanediol, 4,4′-ethylidenediphenol, 4-benzyloxybenzyl alcohol, 1,3-diphenoxy-2-propanol, 4,4′-dimethoxybenzhydrol, 1′-hydroxy-2′-acetonaphthone, 1-acetonaphthol, 2,3,4-trihydroxydiphenylmethane, 4-hydroxybiphenyl, 4-hydroxy-4′-propoxybiphenyl, 4-hydroxy-4′-butoxybiphenyl, diphenylmethane-2,4-diol, 4,4′,4″-trihydroxytriphenylmethane, 4,4′-(1-(p-(4-hydroxy-α,α-dimethylbenzyl)phenyl)ethylidene)diphenol, 4,4′-(2-hydroxybenzylidene)bis(2,3,6-trimethylphenol), 2,6-bis(2-hydroxy-5-methylbenzyl)p-cresol, 1,1,1-tris(p-hydroxyphenyl)ethane and 1,1,2,2-tetrakis(p-hydroxyphenyl)ethane.

The following compounds may also be mentioned as phenols (all are trade names of Honshu Chemical Industry Co., Ltd.).

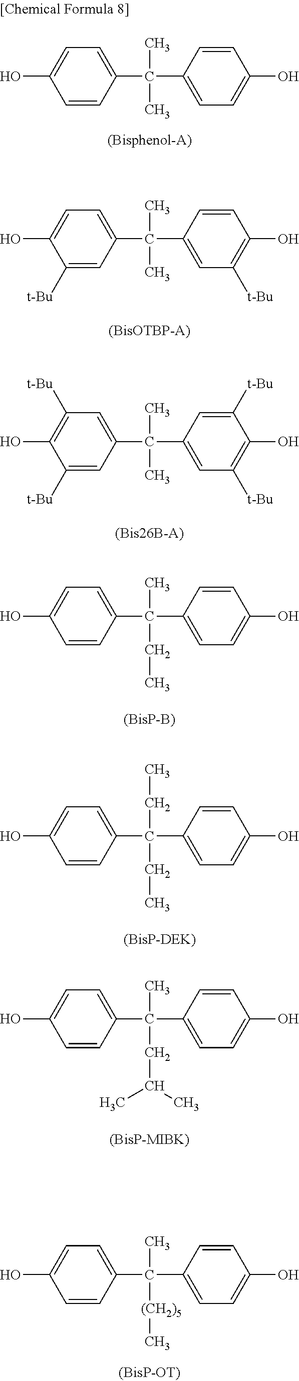

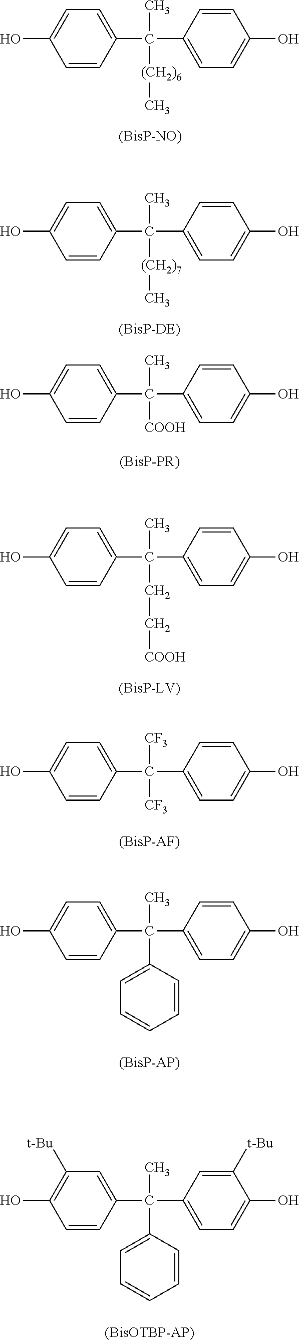

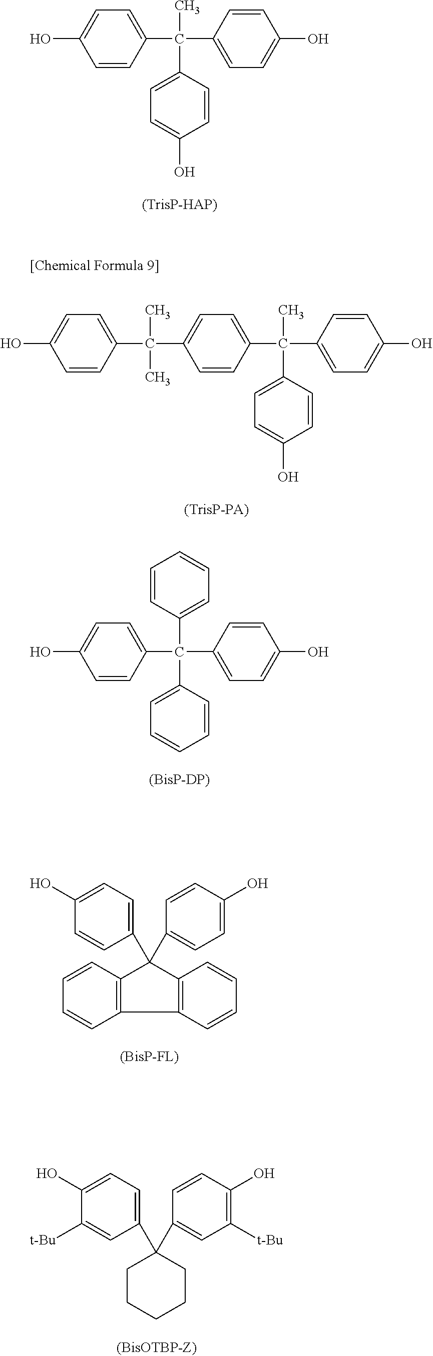

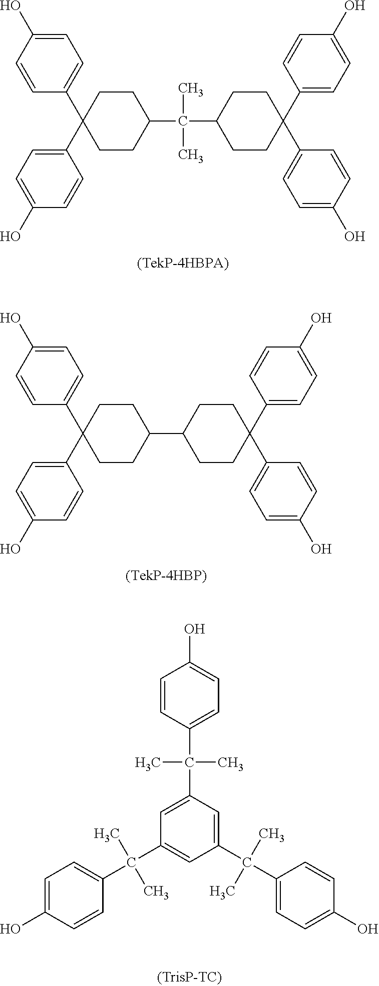

The naphthoquinone diazide sulfonic acid ester can be obtained by a known process, and for example, it may be obtained by reaction between naphthoquinone diazide sulfonic acid chloride and a phenol or alcohol in the presence of a base.

Examples of bases to be used in the reaction include tertiary alkylamines such as trimethylamine, triethylamine, tripropylamine, tributylamine, trihexylamine and trioctylamine, and pyridine, 2,6-lutidine, sodium hydroxide, potassium hydroxide, sodium hydride, potassium-tert-butoxide, sodium methoxide, sodium carbonate, potassium carbonate and the like.

The reaction solvent may be an aromatic solvent such as toluene or xylene, a halogen-based solvent such as chloroform or carbon tetrachloride, an ether solvent such as THF, 1,4-dioxane or diethyl ether, an ester-based solvent such as ethyl acetate or butyl acetate, an ether acetate-based solvent such as propyleneglycol monomethyl ether acetate, a ketone-based solvent such as acetone or isobutyl ketone, or hexane, dimethyl sulfoxide or the like.

A single ester of a phenol or alcohol with naphthoquinone diazide sulfonic acid may be used alone, or two or more may be used in combination.

From the viewpoint of the photosensitive property, the mixing proportion of component (c) is preferably 1-30 mass %, more preferably 3-25 mass % and even more preferably 3-20 mass %, based on the total solid portion of the photosensitive resin composition. If the mixing proportion of component (c) is at least 1 mass %, the dissolution-inhibiting effect in alkali developing solutions will be improved and the photosensitivity will tend to be increased. If the mixing proportion of the component (c) is no greater than 30 mass %, component (c) will not easily be deposited during formation of the coating film, and the coating film will tend to be uniform. In addition, since the concentration of component (c) as the photosensitive agent will not be too high and absorption of light will not be restricted only to the region near the surface of the formed coating film, the light during exposure will reach to the lower sections of the coating film, thus tending to improve the photosensitive property.

When the photosensitive resin composition is to be used in an electronic part or the like, it preferably contains no alkali metals or alkaline earth metals, or if it does contain them, the metal ion concentration in the composition is preferably no greater than 1000 ppm and more preferably no greater than 1 ppm. If the metal ion concentration exceeds 1000 ppm, metal ions will flow more easily into electronic parts comprising the silica coating film obtained from the composition, and this can potentially have adverse effects on the electrical performance itself. It is therefore effective, when necessary, to use an ion-exchange filter or the like to remove the alkali metals or alkaline earth metals from the composition. This does not apply, however, to optical waveguide or other uses, so long as the purpose is not impeded.

The photosensitive resin composition may contain water if necessary, preferably in a range that does not impair the desired properties.

### (Method for Forming Silica Coating Film)

The method for forming a silica coating film according to the invention comprises a coating step in which a photosensitive resin composition of the invention as described above is coated onto a substrate and dried to obtain a coating film, a first exposure step in which prescribed sections of the coating film are exposed, a removal step in which the prescribed sections of the coating film that have been exposed are removed, and a heating step in which the coating film from which the prescribed sections have been removed is heated. The method for forming a silica coating film of the invention may further comprise a coating step in which a photosensitive resin composition of the invention as described above is coated onto a substrate and dried to obtain a coating film, a first exposure step in which prescribed sections of the coating film are exposed, a removal step in which the prescribed sections of the coating film that have been exposed are removed, a second exposure step in which the coating film from which the prescribed sections have been removed is exposed, and a heating step in which the coating film from which the prescribed sections have been removed is heated. Each of these steps will now be explained.

### <Coating Step>

First, a substrate for application of the photosensitive resin composition is prepared. The substrate may be one with a flat surface, or one having electrodes or the like formed thereon with concavoconvexities. Examples of materials for the substrate include organic polymers such as polyethylene terephthalate, polyethylene naphthalate, polyamide, polycarbonate, polyacryl, nylon, polyethersulfone, polyvinyl chloride, polypropylene and triacetylcellulose. A film made of such organic polymers may also be used as the substrate.

The photosensitive resin composition may be coated on such a substrate by a known method. Specific examples of coating methods include spin coating methods, spraying methods, roll coating methods, rotational methods and slit coating methods. The photosensitive resin composition is preferably applied by a spin coating method, which generally allows excellent film formability and film uniformity.

When a spin coating method is used, the photosensitive resin composition is spin coated onto the substrate at preferably 300-3000 rpm and more preferably 400-2000 rpm, to form a coating film. A rotational speed of 300 rpm or greater will tend to improve the film uniformity, while the film formability will tend to be improved if it is no greater than 3000 rpm.

The thickness of the coating film formed in this manner can be adjusted in the following manner, for example. First, during spin coating, the thickness of the coating film can be modified by adjusting the rotational speed and the number of applications. That is, the rotational speed for spin coating can be lowered or the number of applications reduced, to increase the thickness of the coating film. The rotational speed for spin coating can also be raised or the number of applications reduced, to decrease the thickness of the coating film.

For the photosensitive resin composition described above, the concentration of component (a) may be adjusted to modify the thickness of the coating film. For example, the concentration of component (a) may be increased to increase the coating film thickness. The concentration of component (a) may also be reduced to decrease the coating film thickness.

By modifying the coating film thickness in this manner it is possible to modify the thickness of the silica coating film as the final product. The optimal silica coating film thickness will differ depending on the purpose of use. For example, for an interlayer insulating film in an LSI or the like, the silica coating film thickness is preferably 0.01-2 μm; for used as a passivation layer it is preferably 2-40 μm; for liquid crystal purposes it is preferably 0.1-20 μm; for photoresist purposes it is preferably 0.1-2 μm; and for optical waveguide purposes the film thickness is preferably 1-50 μm. Generally speaking, the silica coating film thickness is preferably 0.01-10 μm, more preferably 0.01-5 μm, even more preferably 0.01-3 μm, yet more preferably 0.05-3 μm and most preferably 0.1-3 μm. The photosensitive resin composition of the invention may be suitably used for a silica coating film with a film thickness of 0.5-3.0 μm, it is more suitable for a silica coating film with a film thickness of 0.5-2.5 μm, and it is most suitable for a silica coating film with a film thickness of 1.0-2.5 μm.

When the coating film has been formed on a substrate as described above, the coating film is dried to remove the organic solvent in the coating film. A known method may be employed for drying, and for example, a hot plate may be used. The drying temperature is preferably 50-150° C., more preferably 70-140° C. and even more preferably 80-130° C. A drying temperature of at least 50° C. will tend to allow sufficient removal of the organic solvent. A drying temperature of no higher than 150° C. will prevent decomposition of the photosensitive agent in the film that leads to lower transmittance, and will prevent reduction in solubility in the developing solution as curing of the coating film proceeds, thus tending to improve the exposure sensitivity and resolution.

### <Reduced Pressure Drying Step>

Following formation of the coating film on the substrate by the coating step, a reduced pressure drying step may be carried out before removal of the solvent in the film with a hot plate or the like. The reduced pressure drying has an effect of minimizing variation in the in-plane film thickness upon film formation, and of reducing variation in film thickness after development. Reduced pressure drying also tends to reduce the amount of residual solvent in the resin and minimize the effects of temperature during the subsequent heat treatment. It therefore has the effect of inhibiting variation in aqueous alkali solution solubility due to changes in drying temperature or drying time. The degree of pressure reduction during the reduced pressure drying step is preferably no greater than 150 Pa, more preferably no greater than 100 Pa, even more preferably no greater than 50 Pa and most preferably no greater than 20 Pa. The temperature for reduced pressure drying is preferably 0-100° C., more preferably 10-50° C. and even more preferably 20-30° C. A pressure reduction of no greater than 150 Pa will tend to allow sufficient removal of the solvent. Also, a temperature of no higher than 100° C. will tend to reduce variation in the in-plane film thickness, while a temperature of at least 0° C. will tend to allow sufficient removal of the solvent.

### <First Exposure Step>

Prescribed sections of the obtained coating film are subsequently exposed. The method of exposing the prescribed sections of the coating film may be a known method, and for example, the coating film may be irradiated with radiation through a mask with a prescribed pattern for exposure of the prescribed sections. The radiation used in this case may be, for example, ultraviolet rays such as g-rays (wavelength of 436 nm) or i-rays (wavelength of 365 nm), far ultraviolet rays such as from a KrF excimer laser, X-rays such as synchrotron radiation, or charged particle rays such as an electron beam. Preferred among these are g-rays and i-rays. The exposure dose will normally be 10-2000 mJ/cm², and is preferably 20-200 mJ/cm².

### <Removal Step>

Next, the exposed prescribed sections of the coating film (hereunder referred to as “exposed sections”) are removed to obtain a coating film having the prescribed pattern. The method of removing the exposed sections of the coating film may be a method known in the prior art, and for example, a developing solution may be used for developing treatment to remove the exposed sections, thereby yielding a coating film having the prescribed pattern. The developing solution used in this case is preferably, for example, an aqueous alkali solution of an inorganic alkali such as sodium hydroxide, potassium hydroxide, sodium carbonate, sodium silicate or ammonia water, a primary amine such as ethylamine or n-propylamine, a secondary amine such as diethylamine or di-n-propylamine, a tertiary amine such as triethylamine or methyldiethylamine, an alcohol amine such as dimethylethanolamine or triethanolamine, a quaternary ammonium salt such as tetramethylammonium hydroxide, tetraethylammonium hydroxide or choline, or a cyclic amine such as pyrrole, piperidine, 1,8-diazabicyclo-(5.4.0)-7-undecene or 1,5-diazabicyclo-(4.3.0)-5-nonane, dissolved in water. An appropriate amount of a water-soluble organic solvent, for example, an alcohol such as methanol or ethanol or a surfactant, may also be added to the developing solution. Various organic solvents that dissolve the photosensitive resin composition of the invention may also be used as developing solutions.

The developing method used may be any appropriate method such as puddle development, dipping, reciprocal dipping or the like. Following developing treatment, the patterned film may be processed by rinsing treatment by flow rinsing, for example.

### <Second Exposure Step>

When necessary, the entire surface of the coating film remaining after the removal step may be exposed. This will decompose component (c), which has optical absorption in the visible light range, thus producing a compound with sufficiently low optical absorption in the visible light range. The transparency of the silica coating film as the final product will thus be improved. The radiation used for the exposure may be the same as used in the first exposure step. The exposure dose must be sufficient to thoroughly decompose component (c), and is therefore usually 100-3000 mJ/cm² and preferably 200-2000 mJ/cm².

### <Heating Step>

Finally, the coating film remaining after the removal step is heated for final curing. The heating step yields a silica coating film as the final product. The minimum heating temperature is preferably 250° C. and more preferably 300° C., from the viewpoint of accomplishing thorough curing of the coating film. On the other hand, when a metal wiring layer is present, the maximum heating temperature is preferably 500° C., more preferably 450° C. and most preferably 400° C., from the viewpoint of preventing increased heat input and degradation of the wiring metal.

The heating step is preferably carried out under an inert atmosphere of nitrogen, argon, helium or the like, in which case the oxygen concentration is preferably no greater than 1000 ppm. Also, the heating time is preferably 2-60 minutes and more preferably 2-30 minutes. A heating time of at least 2 minutes will tend to allow sufficient curing of the coating film, and a time of up to 60 minutes will help prevent degradation of the wiring metal by excessive increase in heat input.

The apparatus used for heating may be a heat treatment apparatus such as a quartz tube furnace or other type of furnace, a hot plate, a rapid thermal annealing (RTA) apparatus or the like, or a heat treatment apparatus that also employs EB or UV.

The silica coating film that has been formed by the procedure described above has sufficiently high heat resistance and high transparency, as well as excellent solvent resistance, even under heat treatment at 350° C., for example. A coated film formed from a composition comprising a phenol-based resin such as a novolac resin and a quinone diazide-based photosensitive agent or a composition comprising an acrylic-based resin and a quinone diazide-based photosensitive agent material, as conventionally known components, usually has a maximum heat-resistant temperature of about 230° C., and heat treatment above such temperature causes coloration such as yellowing or browning, and notable reduction in transparency.

A silica coating film formed by the steps described above can be suitably used as an interlayer insulating film in a flat display device, such as a liquid crystal display unit, plasma display, organic EL or field emission display. Such a silica coating film can also be suitably used as an interlayer insulating film in a semiconductor element or the like.

Furthermore, such a silica coating film can be suitably used as member for electronic devices, such as a wafer coating material for a semiconductor element (a surface protecting film, bump protecting film, MCM (multi-chip module) interlayer protecting film or junction coating) or a package material (sealing material or die bonding material).

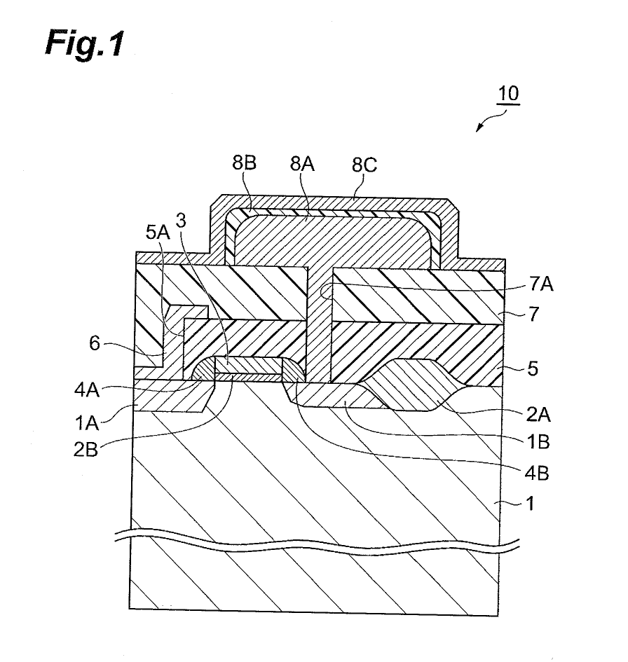

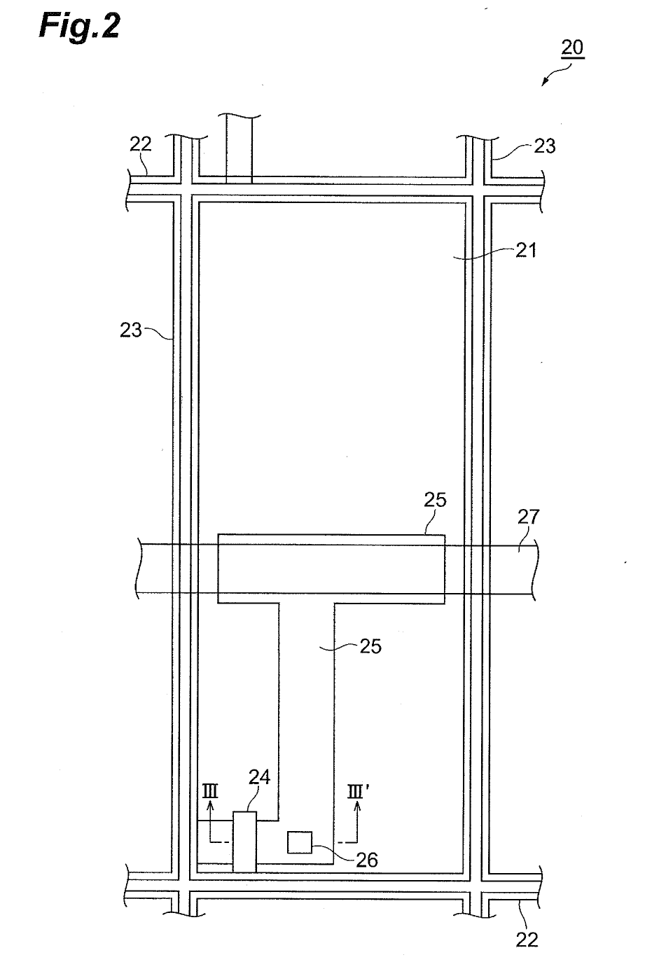

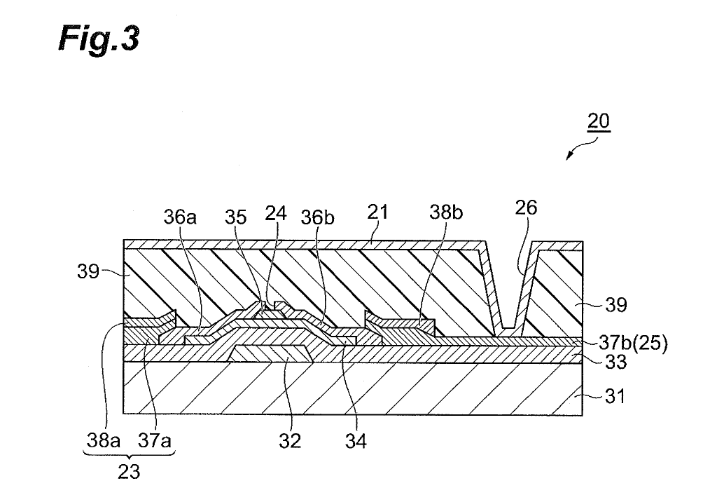

A specific example of an electronic part according to the invention comprising such a silica coating film is the memory cell capacitor shown in FIG. 1, and specific examples of flat display devices according to the invention comprising such a silica coating film include the flat display devices with active matrix substrates shown in FIGS. 2 and 3.

FIG. 1 is a schematic cross-sectional view showing a memory cell capacitor as an embodiment of an electronic part of the invention. The memory capacitor 10 shown in FIG. 1 comprises a silicon wafer 1 (substrate) having diffusion regions 1A and 1B formed on the surface, a gate insulating film 2B provided at a location between the diffusion regions 1A and 1B on the silicon wafer 1, a gate electrode 3 provided on the gate insulating film 2B, a counter electrode 8C provided above the gate electrode 3, and interlayer insulating films 5 and 7 (insulating films) laminated between the gate electrode 3 and counter electrode 8C, in that order from the silicon wafer 1 side.

A side wall oxide film 4A is formed on the diffusion region 1A, in contact with the side walls of the gate insulating film 2B and gate electrode 3. A side wall oxide film 4B is also formed on the diffusion region 1B, in contact with the side walls of the gate insulating film 2B and gate electrode 3. On the side of the diffusion region 1B opposite the gate insulating film 2B, a field oxide film 2A for device isolation is formed between the silicon wafer 1 and interlayer insulating film 5.

The interlayer insulating film 5 is formed covering the gate electrode 3, silicon wafer 1 and field oxide film 2A. The surface of the side of the interlayer insulating film 5 opposite the silicon wafer 1 is flattened. The interlayer insulating film 5 has a side wall located over the diffusion region 1A, and a bit line 6 is formed along it, covering the side wall and diffusion region 1A, and also covering part of the side of the interlayer insulating film 5 opposite the silicon wafer 1. An interlayer insulating film 7 provided on the interlayer insulating film 5 is formed in a manner covering the bit line 6. A contact hole 5A in which the bit line 6 is embedded is formed by the interlayer insulating film 5 and the interlayer insulating film 7.

The surface of the side of the interlayer insulating film 7 opposite the silicon wafer 1 is also flattened. A contact hole 7A is formed running through the interlayer insulating film 5 and interlayer insulating film 7, at a location above the diffusion region 1B. A storage electrode 7A is embedded in the contact hole 7A, and the storage electrode 7A also runs on the side of the interlayer insulating film 7 opposite the silicon wafer 1 side, covering the section surrounding the contact hole 7A. The counter electrode 8C is formed covering the storage electrode 8A and interlayer insulating film 7, and a capacitor insulating film 8B lies between the counter electrode 8C and storage electrode 8A.

The interlayer insulating films 5 and 7 are silica coating films formed from the photosensitive resin composition described above. The interlayer insulating films 5 and 7 are formed, for example, by a step of coating the photosensitive resin composition by spin coating. The interlayer insulating films 5 and 7 may have the same or different compositions.

FIG. 2 is a plan view showing the structure of one picture element section in an active matrix substrate for an embodiment of a flat display device of the invention. In FIG. 2, a plurality of picture element electrodes 21 are provided in the form of a matrix on the active matrix substrate 20, and there are provided gate wiring 22 for supply of a scanning signal and source wiring 23 for supply of a display signal, running around the picture element electrodes 21 in a mutually orthogonally crossing manner. The gate wiring 22 and source wiring 23 partially overlap with the outer peripheries of the picture element electrodes 21. At each crossing section of the gate wiring 22 and source wiring 23 there is provided a TFT 24 as a switching element, connected to a picture element electrode 21. The gate wiring 22 is connected to a gate electrode 32 of the TFT 24, and driving of the TFT 24 is controlled by a signal inputted to the gate electrode. Also, the source wiring 23 is connected to a source electrode of the TFT 24, and a data signal is inputted to the source electrode of the TFT 24. In addition, a drain electrode of the TFT 24 is connected to the picture element electrode 21 via a connecting electrode 25 and a contact hole 26, while also being connected to an additional capacity electrode (not shown), as one electrode with additional capacity, via the connecting electrode 25. The additional capacity counter electrode 27, as another electrode with additional capacity, is connected to common wiring.

FIG. 3 is a cross-sectional view of the active matrix substrate of FIG. 2 along III-III′. In FIG. 3, a gate electrode 32 connected to gate wiring 22 is provided on a transparent insulating board 31, and a gate insulating film 33 is provided over and covering it. A semiconductor layer 34 is provided over this, superposed over the gate electrode 32, and a channel protecting layer 35 is provided at the center. An n+Si layer, serving as a source electrode 36a and drain electrode 36b, is also provided in a segmented manner on the channel protecting layer 35, covering both ends of the channel protecting layer 35 and portions of the semiconductor layer 34. At the edge of the source electrode 36a, as one of the n+Si layers, there are provided a transparent conductive film 37a and a metal layer 38a, which form source wiring 23 having a two-layer structure. At the edge of the drain electrode 36b, as the other n+Si layer, there are provided a transparent conductive film 37b and a metal layer 38b, the transparent conductive film 37b extending and connecting the drain electrode 36b and picture element electrode 21, while also forming a connecting electrode 25 connected to an additional capacity electrode (not shown) as one electrode with additional capacity. An interlayer insulating film 39 is also provided, covering the TFT 24, gate wiring 22 and source wiring 23, and the top of the connecting electrode 25. A transparent conductive film, serving as the picture element electrode 21, is provided on the interlayer insulating film 39, and is connected to the drain electrode 36b of the TFT 24 by the connecting electrode 25, via a contact hole 26 running through the interlayer insulating film 39.

The active matrix substrate of this embodiment has the construction described above, and the active matrix substrate may be produced in the following manner, for example.

First, a gate electrode 32, gate insulating film 33, semiconductor layer 34, channel protecting layer 35, and n+Si layers to serve as the source electrode 36a and drain electrode 36b, are formed in that order on a transparent insulating board 31, such as a glass panel. The fabrication process up to this point may be carried out in the same manner as a method for producing a conventional active matrix substrate.

Next, transparent conductive films 37a, 37b and metal layers 38a, 38b, which are to compose the source wiring 23 and connecting electrode 25, are formed in that order by sputtering for patterning in the prescribed shape.

Over this, the photosensitive resin composition which is to constitute the interlayer insulating film 39 is formed to a thickness of, for example, 2 μm by spin coating. The formed coating film is exposed through a mask, and developing treatment with an alkali solution is performed to form an interlayer insulating film 39. Only the exposed sections are etched with the alkali solution during this step, and contact holes 26 are formed running through the interlayer insulating film 39.

Next, the transparent conductive film that is to serve as the picture element electrode 21 is formed by sputtering and patterned. This causes each picture element electrode 21 to be connected to the transparent conductive film 38b which is connected to the drain electrode 36b of the TFT 24, via each of the contact holes 26 running through the interlayer insulating film 39. This procedure allows production of an active matrix substrate as described above.

Since the active matrix substrate obtained in this manner thus has a thick interlayer insulating film 39 between the gate wiring 22, source wiring 23 and TFT 24 and the picture element electrode 21, the picture element electrode 21 can overlap with the wirings 22, 23 and the TFT 24, while the surface can also be flattened. Consequently, when a flat display device is constructed with a liquid crystal situated between an active matrix substrate and opposing substrates, the open area ratio can be increased, and the electric field generated by the wirings 22, 23 is shielded by the picture element electrode 21, thus allowing discrimination to be minimized.

Also, the photosensitive resin composition, which is to compose the interlayer insulating film 39, has a relative permittivity value of between 3.0 and 3.8, which is lower than the relative permittivity of an inorganic film (relative permittivity of silicon nitride=8), and high transparency, and can therefore be easily increased in thickness by spin coating. It is thus possible to reduce the capacity between the gate wiring 22 and picture element electrode 21, and the capacity between the source wiring 23 and picture element electrode 21, for a lower time constant, while also further reducing the effects on display by crosstalk between the capacity components of the wirings 22, 23 and picture element electrode 21, so that a satisfactory bright display can be obtained. Furthermore, by patterning with exposure and alkali development, it is possible to obtain a satisfactory taper shape for the contact hole 26 and to achieve satisfactory connection between the picture element electrode 21 and connecting electrode 37b. In addition, since a thin-film can be formed by spin coating using the photosensitive resin composition, it is possible to easily form thin-films with thicknesses of several μm, while a photoresist step is also unnecessary for patterning, thus providing an advantage in terms of productivity. The photosensitive resin composition described above, used as an interlayer insulating film 39, is colored prior to coating, but may be subjected to exposure treatment across the entire surface after patterning for increased transparency. Such transparency treatment of the resin can be accomplished not only optically, but also chemically.

Exposure of the photosensitive resin composition which is used as the interlayer insulating film 39 for this embodiment will usually be accomplished using light rays from a mercury lamp, containing emission lines of i rays (wavelength of 365 nm), h rays (wavelength of 405 nm) and g rays (wavelength of 436 nm). The photosensitive resin composition used is preferably a photosensitive resin composition having radiation sensitivity (absorption peak) in i-rays, which have the highest energy (shortest wavelength) among these emission lines. This will allow the contact hole machining precision to be increased, while also minimizing coloration caused by the photosensitive agent. Short-wavelength ultraviolet rays from an excimer laser may also be used.

### EXAMPLES

Concrete examples of the present invention will now be explained, with the understanding that the invention is not limited to the examples.

### (Synthesis of 3-Acetoxypropyltrimethoxysilane)

In a 1 L four-necked flask equipped with a stirrer, reflux condenser, dropping funnel and thermometer there were added 500 g of toluene, 250.0 g (1.258 mol) of 3-chloropropyltrimethoxysilane and 129.6 g (1.321 mol) of potassium acetate, the mixture was stirred, and then 5.84 g (0.0181 mol) of tetra-n-butylammonium bromide was added for reaction at 90-100° C. for 2 hours. The cooled salt product was then suction filtered to obtain a yellow solution. The toluene in the obtained solution was distilled off under reduced pressure with an evaporator, and then subjected to vacuum distillation to obtain 162.8 g (0.732 mol) of a colorless transparent fraction having a distillation temperature of 80-81° C. at pressure reduction of 0.4 kPa. According to the results of GC analysis of the obtained fraction, the GC purity was 99.0%, and the results of NMR and IR analysis identified the compound as 3-acetoxypropyltrimethoxysilane.

The spectral data for the obtained compound were as follows.

Infrared absorption spectrum (IR) data:

2841, 2945 cm⁻¹ (—CH₃), 1740 cm⁻¹ (—COO—), 1086 cm⁻¹ (Si—O)

Nuclear magnetic resonance spectrum (NMR) data (¹H-NMR solvent: CDCl₃):

0.644-0.686 ppm (dd, 2H, —CH₂—), 1.703-1.779 ppm (m, 2H, —CH₂—), 2.045 ppm (s, 3H, CH₃CO—), 3.575 ppm (s, 9H, CH₃O—), 4.019-4.052 ppm (t, 2H, —COO—CH₂—).

### (Production of Siloxane Resin)

### (1) Synthesis of Siloxane Resin A (Compound Represented by the Following Formula (10), Corresponding to Component (a) Above).

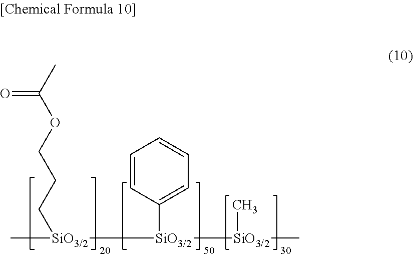

[In formula (10), 20, 50 and 30 represent the molar ratios of the starting materials corresponding to each position.]

In a 500 mL four-necked flask equipped with a stirrer, reflux condenser, dropping funnel and thermometer there were charged 55.8 g of toluene and 35.7 g of water, and then 3.12 g (0.03 mol) of 35% hydrochloric acid was added. Next, a solution of 13.5 g (0.0605 mol) of 3-acetoxypropyltrimethoxysilane, 30.0 g (0.151 mol) of phenyltrimethoxysilane, and 12.4 g (0.0908 mol) of methyltrimethoxysilane dissolved in 27.9 g of toluene was added dropwise at 20-30° C. Upon completion of the dropwise addition, the mixture was aged for 2 hours at the same temperature. The reaction solution was analyzed by GC (gas chromatography) at this point, and it was confirmed that no starting materials remained. Toluene and water were then added to the reaction solution and the product was extracted into the organic phase, washing was performed with a sodium hydrogencarbonate aqueous solution, and the solution was washed with water to neutrality. Next, the organic phase was recovered and the toluene was removed to obtain 34.6 g of the target siloxane resin A as a viscous liquid. The obtained siloxane resin A was dissolved in propyleneglycol monomethyl ether acetate, to obtain a solution of siloxane resin A with the solid concentration adjusted to 50 mass %. The weight-average molecular weight of siloxane resin A was measured by GPC to be 1050.

### (2) Production of Siloxane Resin A′ (Purified Siloxane Resin A)

After charging 69.2 g of the siloxane resin A solution (solid portion: 34.6 g) and 69.2 g of methyl isobutyl ketone in a 300 mL separatory funnel and rendering the solution uniform, 34.6 g of ion-exchanged water was added and washing was performed 3 times. Upon washing and reaching an aqueous phase pH of 7.0, the organic phase was recovered and concentrated to obtain 66.3 g of the target siloxane resin A′ as a viscous liquid. The obtained siloxane resin A′ was dissolved in propyleneglycol monomethyl ether acetate, to obtain a solution of siloxane resin A′ with the solid concentration adjusted to 50 mass %.

(3) Production of Siloxane Resin B (Siloxane Resin A with Increased Molecular Weight)

A solution of 450 g of the siloxane resin A solution (solid portion: 225 g) concentrated to 250 g was heated and stirred in an oil bath at 150° C. for 12 hours, to obtain 250 g of the target siloxane resin B as a viscous liquid. The obtained siloxane resin B was dissolved in propyleneglycol monomethyl ether acetate, to obtain a solution of siloxane resin B with the solid concentration adjusted to 50 mass %. The weight-average molecular weight of siloxane resin B was measured by GPC to be 2680.

### (4) Production of Siloxane Resin B′ (Purified Siloxane Resin B)

After charging 69.2 g of the siloxane resin B solution (solid portion: 34.6 g) and 69.2 g of methyl isobutyl ketone in a 300 mL separatory funnel and rendering the solution uniform, 34.6 g of ion-exchanged water was added and washing was performed 3 times. Upon washing and reaching an aqueous phase pH of 7.0, the organic phase was recovered and concentrated to obtain 66.3 g of the target siloxane resin B′ as a viscous liquid. The obtained siloxane resin B′ was dissolved in propyleneglycol monomethyl ether acetate, to obtain a solution of siloxane resin B′ with the solid concentration adjusted to 50 mass %.

### (5) Synthesis of Siloxane Resin C (Compound Represented by the Following Formula (6), Corresponding to Component (d) Above).

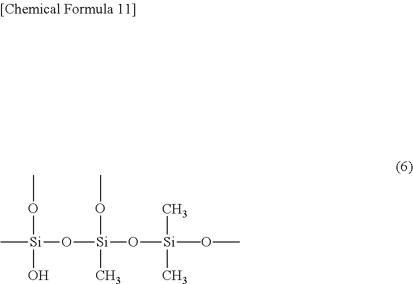

In a 2000 mL four-necked flask equipped with a stirrer, reflux condenser, dropping funnel and thermometer there was charged a solution of 315.6 g of tetraethoxysilane, 405.5 g of methyltriethoxysilane and 112.6 g of diethoxydimethylsilane dissolved in 430.2 g of propyleneglycol monomethyl ether acetate, and 236.1 g of a maleic acid aqueous solution adjusted to 0.012 mass % was dropped therein over a period of 60 minutes while stirring. Upon completion of the dropwise addition, reaction was conducted for 3 hours and the reaction solution was aged for 1 week to obtain 1500.0 g of a siloxane resin C solution with a solid concentration of 20 mass %.

### (6) Production of Siloxane Resin C′ (Purified Siloxane Resin C)

After charging 500 g of the siloxane resin C solution (solid portion: 100 g) and 500 g of methyl isobutyl ketone in a 2000 mL separatory funnel and rendering the solution uniform, 250 g of ion-exchanged water was added and washing was performed 3 times. Upon washing and reaching an aqueous phase pH of 6.0, the organic phase was recovered and concentrated to obtain 196 g of concentrate of the target siloxane resin C′ as a viscous liquid. Propyleneglycol monomethyl ether acetate was added to the obtained concentrate of siloxane resin C′, to obtain a solution of siloxane resin C′ with the solid concentration adjusted to 50 mass %.

### (7) Synthesis of Siloxane Resin D: Phenylsilsesquioxane (Compound Represented by the Following Formula (7))

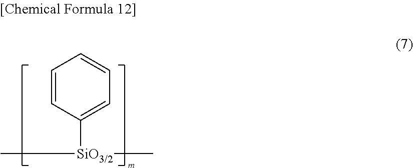

[m represents an integer.]

In a 500 mL four-necked flask equipped with a stirrer, reflux condenser, dropping funnel and thermometer there were charged 55.8 g of toluene and 35.7 g of water, and then 3.12 g (0.03 mol) of 35% hydrochloric acid was added. Next, a solution of 48.0 g (0.242 mol) of phenyltrimethoxysilane dissolved in 27.9 g of toluene was added dropwise at 20-30° C. Upon completion of the dropwise addition, the mixture was aged for 2 hours at the same temperature. The reaction solution was analyzed by GC at this point, and it was confirmed that no starting materials remained. Toluene and water were then added and the product was extracted into the organic phase, washing was performed with a sodium hydrogencarbonate aqueous solution, and the solution was washed with water to neutrality. Next, the organic phase was recovered and the toluene was removed to obtain 34.6 g of the target siloxane resin D as a viscous liquid. The obtained siloxane resin D was dissolved in propyleneglycol monomethyl ether acetate, to obtain a solution of siloxane resin D with the solid concentration adjusted to 50 mass %. The weight-average molecular weight of comparative siloxane resin D was measured by GPC to be 1000.

(Synthesis of Naphthoquinone Diazide Sulfonic Acid Ester)

### (1) Synthesis of Naphthoquinone Diazide Sulfonic Acid Ester A (Corresponding to Component (c))

In a 1000 mL four-necked flask equipped with a stirrer, reflux condenser, dropping funnel and thermometer there were dissolved 21.23 g (0.05 mol) of TrisP-PA (trade name of Honshu Chemical Industry Co., Ltd., trisphenol-novolac) and 37.62 g (0.14 mol) of 5-naphthoquinone diazide sulfonylic acid chloride in 450 g of 1,4-dioxane under a dry nitrogen stream, and the mixture was adjusted to room temperature (25° C.). To this there was added dropwise 15.58 g (0.154 mol) of triethylamine combined with 50 g of 1,4-dioxane, taking care that the temperature in the system did not rise 35° C. or above. Upon completion of the dropwise addition, the mixture was stirred at 30° C. for 2 hours. The triethylamine salt was filtered and the filtrate was poured into water. The deposited precipitate was then collected by filtration. The precipitate was dried with a vacuum dryer to obtain 48.36 g of a solid (naphthoquinone diazide sulfonic acid ester A).

### (2) Synthesis of Naphthoquinone Diazide Sulfonic Acid Ester B (Corresponding to Component (c))

In a 200 mL four-necked flask equipped with a stirrer, reflux condenser, dropping funnel and thermometer there were charged 5.41 g of m-cresol and 50 g of tetrahydrofuran, and then 13.43 g of 1,2-diazonaphthoquinone-5-sulfonyl chloride and 5.06 g of triethylamine were added at room temperature (25° C.), prior to reaction for 4 hours at room temperature (25° C.). Upon completion of the reaction, the deposited solid portion was filtered. After adding 300 g of methyl isobutyl ketone to the filtered solid portion for dissolution, the solution was washed twice with 50 g of ion-exchanged water, and the solvent was removed in a warm bath under reduced pressure to obtain 14.7 g of a solid (naphthoquinone diazide sulfonic acid ester B).

### (3) Synthesis of Naphthoquinone Diazide Sulfonic Acid Ester C (Corresponding to Component (c))

In a 200 mL four-necked flask equipped with a stirrer, reflux condenser, dropping funnel and thermometer there were charged 5.4 g of 1,2-diazonaphthoquinone-5-sulfonyl chloride (DNQ-5Cl), and then 30 g of tetrahydrofuran (THF) was added and the DNQ-5Cl was completely dissolved. Next, 53.9 g of dipropylene glycol was added to the solution at room temperature (25° C.) and the mixture was dissolved to uniformity. A solution of 4.47 g of triethylamine diluted with 4.47 g of THF was added dropwise to the aforementioned solution with a dropping funnel over a period of 1 hour at room temperature (25° C.), and then reaction was conducted for 4 hours at room temperature (25° C.). Upon completion of the reaction, the deposited solid portion was filtered to obtain 90 g of a solution. After adding 90 g of methyl isobutyl ketone to the obtained solution and uniformly dissolving it therein, there were further added 45 g of ion-exchanged water, as well as 15 g of a 5% hydrochloric acid solution while using pH test paper to confirm acidity (pH<5) of the aqueous layer, for extraction. Next, 45 g of ion-exchanged water was added and washing was performed 3 times, upon which the aqueous layer was neutral (pH: 6-7). The solvent was removed from the obtained solution in a warm bath under reduced pressure, to obtain 6.73 g of an oily compound (naphthoquinone diazide sulfonic acid ester C). The solid concentration of the obtained compound was 71 mass %.

### Preparation of Photosensitive Resin Composition

### Example 1

To 5.0 g of a solution of siloxane resin B (solid portion: 2.5 g) there were added 0.2 g of naphthoquinone diazide sulfonic acid ester A and 5.6 g of propyleneglycol methyl ether acetate, and the mixture was stirred and dissolved at room temperature (25° C.) for 30 minutes to prepare a photosensitive resin composition for Example 1.

### Example 2

To 5.0 g of a solution of siloxane resin B′ (solid portion: 2.5 g) there were added 0.2 g of naphthoquinone diazide sulfonic acid ester A and 5.6 g of propyleneglycol methyl ether acetate, and the mixture was stirred and dissolved at room temperature (25° C.) for 30 minutes to prepare a photosensitive resin composition for Example 2 (Examples 2-A and 2-B).

### Example 3

To 5.0 g of a solution of siloxane resin B′ (solid portion: 2.5 g) there were added 0.2 g of naphthoquinone diazide sulfonic acid ester B and 5.6 g of propyleneglycol methyl ether acetate, and the mixture was stirred and dissolved at room temperature (25° C.) for 30 minutes to prepare a photosensitive resin composition for Example 3.

### Example 4

To 5.0 g of a solution of siloxane resin B′ (solid portion: 2.5 g) there were added 0.28 g of naphthoquinone diazide sulfonic acid ester C (solid portion: 0.2 g) and 5.52 g of propyleneglycol methyl ether acetate, and the mixture was stirred and dissolved at room temperature (25° C.) for 30 minutes to prepare a photosensitive resin composition for Example 4.

### Example 5

To 3.5 g of a solution of siloxane resin A (solid portion: 1.75 g) there were added 3.75 g of a solution of siloxane resin C (solid portion: 0.75 g), 0.28 g of naphthoquinone diazide sulfonic acid ester C (solid portion: 0.2 g) and 3.27 g of propyleneglycol methyl ether acetate, and the mixture was stirred and dissolved at room temperature (25° C.) for 30 minutes to prepare a photosensitive resin composition for Example 5.

### Example 6

To 3.5 g of a solution of siloxane resin A′ (solid portion: 1.75 g) there were added 1.5 g of a solution of siloxane resin C′ (solid portion: 0.75 g), 0.28 g of naphthoquinone diazide sulfonic acid ester C (solid portion: 0.2 g) and 5.52 g of propyleneglycol methyl ether acetate, and the mixture was stirred and dissolved at room temperature (25° C.) for 30 minutes to prepare a photosensitive resin composition for Example 6 (Example 6-A and Example 6-B).

### Comparative Example 1

To 5.0 g of a solution of siloxane resin D (solid portion: 2.5 g) there were added 0.2 g of naphthoquinone diazide sulfonic acid ester A and 5.6 g of propyleneglycol methyl ether acetate, and the mixture was stirred and dissolved at room temperature (25° C.) for 30 minutes to prepare a photosensitive resin composition for Comparative Example 1.

### Comparative Example 2

To 5.0 g of a solution of siloxane resin D (solid portion: 2.5 g) there were added 0.28 g of naphthoquinone diazide sulfonic acid ester C (solid portion: 0.2 g) and 5.52 g of propyleneglycol methyl ether acetate, and the mixture was stirred and dissolved at room temperature (25° C.) for 30 minutes to prepare a photosensitive resin composition for Comparative Example 2.

The compositions of the photosensitive resin compositions of the examples and comparative examples (units: g) are shown in Table 1.

TABLE 1

| | Example | | | | | | | | Comp. Ex. | |
|---|---|---|---|---|---|---|---|---|---|---|
| | 1 | 2-A | 2-B | 3 | 4 | 5 | 6-A | 6-B | 1 | 2 |
| Siloxane resin A solution | — | — | — | — | — | 3.5 | — | — | — | — |
| Siloxane resin A′ solution | — | — | — | — | — | — | 3.5 | 3.5 | — | — |
| Siloxane resin B solution | 5 | — | — | — | — | — | — | — | — | — |
| Siloxane resin B′ solution | — | 5 | 5 | 5 | 5 | — | — | — | — | — |
| Siloxane resin C solution | — | — | — | — | — | 3.75 | — | — | — | — |
| Siloxane resin C′ solution | — | — | — | — | — | — | 1.5 | 1.5 | — | — |
| Siloxane resin D solution | — | — | — | — | — | — | — | — | 5 | 5 |
| Naphthoquinone diazide | 0.2 | 0.2 | 0.2 | — | — | — | — | — | 0.2 | — |
| sulfonic acid ester A | | | | | | | | | | |
| Naphthoquinone diazide | — | — | — | 0.2 | — | — | — | — | — | — |
| sulfonic acid ester B | | | | | | | | | | |
| Naphthoquinone diazide | — | — | — | — | 0.28 | 0.28 | 0.28 | 0.28 | — | 0.28 |
| sulfonic acid ester C | | | | | | | | | | |
| Propyleneglycol methyl | 5.6 | 5.6 | 5.6 | 5.6 | 5.52 | 3.27 | 5.52 | 5.52 | 5.6 | 5.52 |
| ether acetate | | | | | | | | | | |

### <Production of Silica Coating Film>

The photosensitive resin compositions obtained in Examples 1-6 and Comparative Examples 1 and 2 were filtered with a PTFE filter. Each was spin coated onto a silicon wafer or glass panel for 30 seconds at a rotational speed for a film thickness of 1.5 μm after removal of the solvent. The glass panel used was one without absorption in the visible light range.

Only in Example 2-B and Example 6-B, there was introduced a drying step for 10 minutes under conditions of 133 Pa pressure reduction, 25° C. using a vacuum dryer (trade name, “VOS-300VD” by Elely), after the spin coating.

A hot plate was then used for drying at 90-140° C. for 2 minutes to remove the solvent. The obtained coating film was exposed with an exposure dose of 100 mJ/cm² through a prescribed pattern mask, using a PLA-600F projection exposure device by Canon. Next, a 2.38 mass % or 1.50 mass % tetramethylammonium hydroxide (TMAH) aqueous solution was used for dissolution of the exposed sections by reciprocal dipping at 25° C. for 90 seconds, as developing treatment. This was followed by flow rinsing with purified water and drying to form a pattern. Next, the entire surface of the film was exposed with an exposure dose of 1000 mJ/cm² using a PLA-600F projection exposure device by Canon. It was then heated for 30 minutes at 350° C. in a quartz tube furnace with the O₂ concentration controlled to less than 1000 ppm, for final curing of the pattern to obtain a silica coating film.

Table 2 shows the use of reduced pressure drying during silica coating film production, the hot plate temperature and the tetramethylammonium hydroxide (TMAH) aqueous solution concentration, for Examples 1-6 and Comparative Examples 1 and 2.

TABLE 2

| | Example | | | | | | | | Comp. Ex. | |
|---|---|---|---|---|---|---|---|---|---|---|
| | 1 | 2-A | 2-B | 3 | 4 | 5 | 6-A | 6-B | 1 | 2 |
| Vacuum drying step | No | No | Yes | No | No | No | No | Yes | No | No |
| Hot plate temperature (° C.) | 90 | 90 | 90 | 90 | 90 | 125 | 125 | 125 | 125 | 125 |
| TMAH concentration (mass %) | 1.5 | 1.5 | 1.5 | 1.5 | 1.5 | 2.38 | 2.38 | 2.38 | 2.38 | 2.38 |

### <Evaluation of Coated Films>

The silica coating films formed from the photosensitive resin compositions of Examples 1-6 and Comparative Examples 1 and 2 by the methods described above were evaluated by the following methods.

### [Evaluation of Resolution]

The resolution was evaluated by determining whether or not a 5 μm square through-hole pattern had been formed in the silica coating film formed on the silicon wafer. Specifically, an evaluation of “A” was assigned when a 5 μm square through-hole pattern had clearly formed based on observation using an electron microscope S-4200 (product of Hitachi Instruments Service Co., Ltd.), and an evaluation of “B” was assigned when a through-hole pattern was not clearly formed, such as when residue of resin remained inside the through-hole.

### [Measurement of Transmittance]

The transmittance of the silica coating film coated on the glass panel was measured at a wavelength of 300 nm-800 nm using an UV3310 device by Hitachi, Ltd., and the value at a wavelength of 400 nm was recorded as the transmittance.

### [Evaluation of Heat Resistance]

An evaluation of “A” was assigned when the percentage reduction in film thickness after final curing of the silica coating film formed on the silicon wafer with respect to the film thickness after removal of the solvent was less than 10%, and an evaluation of “B” was assigned when it was 10% or greater. The film thickness is the film thickness measured with an L116B ellipsometer by Gartner, Inc., and specifically it is the film thickness determined from the phase contrast produced by irradiation of the coated film with a He—Ne laser.

### [Evaluation of Crack Resistance]

The presence of in-plane cracking of the silica coating film formed on the silicon wafer was confirmed by observation at 10-100× magnification with a metallographic microscope. An evaluation of “A” was assigned when no cracking was observed, and an evaluation of “B” was assigned when cracking was observed.

### [Evaluation of Temperature Dependence]

The resolution of the silica coating film formed on the silicon wafer was confirmed, when the temperature in the step of solvent removal with a hot plate after spin coating during formation of the silica coating film was set to a temperature of 5° C. higher than the temperature listed in Table 2. An evaluation of “A” was assigned when a 5 μm square through-hole pattern penetrated, based on observation using an S-4200 electron microscope (product of Hitachi Instruments Service Co., Ltd.), and an evaluation of “B” was assigned when not penetrated.

[Pattern Formation after Curing]

The pattern of the silica coating film formed on the silicon wafer after final curing for 30 minutes at 350° C. was confirmed. An evaluation of “A” was assigned when a 5 μm square through-hole pattern penetrated without alteration from before curing, based on observation using an 5-4200 electron microscope (product of Hitachi Instruments Service Co., Ltd.), and an evaluation of “B” was assigned when the pattern underwent alteration (deterioration) from before curing.

### [Evaluation of Stability]

The photosensitive resin compositions prepared in Examples 1-6 were stored for 5 days in a cleanroom with a room temperature of 24° C. and a relative humidity of 50%. Each of the stored photosensitive resin compositions was used to form a silica coating film on a silicon wafer by the same method described above, and the resolution was confirmed. An evaluation of “A” was assigned when a 5 μm square through-hole pattern had clearly formed, based on observation using an S-4200 electron microscope (product of Hitachi Instruments Service Co., Ltd.), an evaluation of “B” was assigned when a pattern had essentially formed but slight dissolved residue was observed, and an evaluation of “C” was assigned when a pattern had not clearly formed.

### <Evaluation Results>

Table 3 shows the results of evaluating the silica coating films formed from the photosensitive resin compositions of Examples 1-6 and Comparative Examples 1 and 2. The silica coating films formed from the photosensitive resin compositions of Comparative Examples 1 and 2 had insufficient resolution and heat resistance, which are the subject of the invention, and therefore their temperature dependence, stability and post-curing pattern shapes were not evaluated.

TABLE 3

| | | | | | | | Post-curing |
|---|---|---|---|---|---|---|---|
| | | Transmit- | Heat | | Temperature | | pattern |
| | Resolution | tance | resistance | Cracking | dependence | Stability | shape |
| Example 1 | A | ≧90% | A | A | A | B | B |
| Example 2-A | A | ≧90% | A | A | A | A | B |
| Example 2-B | A | ≧90% | A | A | A | A | B |
| Example 3 | A | ≧90% | A | A | A | A | B |
| Example 4 | A | ≧90% | A | A | B | A | B |
| Example 5 | A | ≧90% | A | A | B | C | A |
| Example 6-A | A | ≧90% | A | A | B | B | A |
| Example 6-B | A | ≧90% | A | A | A | B | A |
| Comp. Ex. 1 | B | ≧90% | B | A | — | — | — |
| Comp. Ex. 2 | B | ≧90% | B | A | — | — | — |

The results shown in Table 3 demonstrate that the photosensitive resin compositions of Examples 1-6 can yield silica coating films with excellent resolution, transmittance, heat resistance and crack resistance.

In terms of temperature dependence, excellent characteristics were exhibited by Examples 1-3 that employed phenol-based photosensitive agents. As clearly seen by comparing Example 6-A and

Example 6-B, the temperature dependence can be improved by a reduced pressure drying step after coating the photosensitive resin composition and prior to drying with a hot plate. Also, comparison between Example 2-A and Example 2-B confirmed that, while the temperature dependence is not altered with a composition having excellent temperature dependence even if a reduced pressure drying step is carried out, it is at least not reduced. A reduced pressure drying step is therefore effective for improving the temperature dependence.

In terms of stability, particularly excellent characteristics were exhibited by Examples 2-4 which had the siloxane resin pH adjusted to 5.0-7.0. Therefore, adjustment of the pH is effective in cases with a long storage time until use of the photosensitive resin composition of the invention.

Examples 5 and 6, wherein a second siloxane resin was added, exhibited excellent characteristics in terms of the post-curing pattern shape.

These results confirmed that the photosensitive resin composition of the invention has excellent resolution, heat resistance and crack resistance, and that addition of other components as necessary can also impart properties such as temperature dependence and storage stability. Incidentally, the examples only describe photosensitive resin compositions from which high-transmittance silica coating films are obtained, but low-transmittance films may also be provided, depending on the purpose.

1. A photosensitive resin composition comprising:
component (a): a first siloxane resin obtained by hydrolytic condensation of a first silane compound comprising a compound represented by the following formula (1), component (b): a solvent in which component (a) dissolves, and
component (c): an ester of a phenol or alcohol and naphthoquinone diazide sulfonic acid: 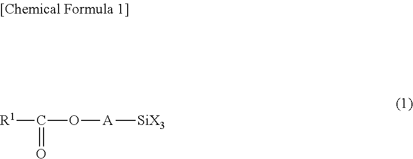
[In formula (1), R¹ represents an organic group, A represents a divalent organic group, and X represents a hydrolyzable group, where the multiple X groups in the same molecule may be the same or different].

2. A photosensitive resin composition according to claim 1, wherein component (c) includes an ester of a phenol or an alcohol with one or more aryl groups, and naphthoquinone diazide sulfonic acid.

3. A photosensitive resin composition according to claim 1, which further comprises component (d): a second siloxane resin obtained by hydrolytic condensation of a second silane compound not comprising a compound represented by formula (1) above but comprising a compound represented by the following formula (2):
[Chemical Formula 2]
R²ₙSiX₄₋ₙ (2)
[In formula (2), R² represents an H atom or an organic group, X represents a hydrolyzable group and n represents an integer of 0-3, with the proviso that when n is 2 or smaller the multiple X groups in the same molecule may be the same or different, and when n is 2 or 3 the multiple R² groups in the same molecule may be the same or different].

4. A photosensitive resin composition according to claim 1, wherein the first silane compound further comprises a compound represented by the following formula (3):
[Chemical Formula 3]
R³SiX₃ (3)
[In formula (3), R³ represents an organic group, and X represents a hydrolyzable group, where the multiple X groups in the same molecule may be the same or different].

5. A photosensitive resin composition according to claim 1, wherein component (b) comprises at least one solvent selected from the group consisting of ether acetate-based solvents, ether-based solvents, ester-based solvents, alcohol-based solvents and ketone-based solvents.

6. A method for forming a silica coating film, which comprises:
a coating step in which a photosensitive resin composition according to claim 1 is coated onto a substrate and dried to obtain a coating film, a first exposure step in which prescribed sections of the coating film are exposed, a removal step in which the prescribed sections of the coating film that have been exposed are removed, and
a heating step in which the coating film from which the prescribed sections have been removed is heated.

7. A method for forming a silica coating film, which comprises:
a coating step in which a photosensitive resin composition according to claim 1 is coated onto a substrate and dried to obtain a coating film,
a first exposure step in which prescribed sections of the coating film are exposed,
a removal step in which the prescribed sections of the coating film that have been exposed are removed,
a second exposure step in which the coating film from which the prescribed sections have been removed is exposed, and
a heating step in which the coating film from which the prescribed sections have been removed is heated.

8. A semiconductor device comprising a substrate and a silica coating film formed by the method according to claim 6 on the substrate.

9. A flat display device comprising a substrate and a silica coating film formed by the method according to claim 6 on the substrate.

10. An electronic device member comprising a substrate and a silica coating film formed by the method according to claim 6 on the substrate.

11. A semiconductor device comprising a substrate and a silica coating film formed by the method according to claim 7 on the substrate.

12. A flat display device comprising a substrate and a silica coating film formed by the method according to claim 7 on the substrate.

13. An electronic device member comprising a substrate and a silica coating film formed by the method according to claim 7 on the substrate.

14. A photosensitive resin composition according to claim 3, wherein the first silane compound further comprises a compound represented by the following formula (3):
[Chemical Formula 3]
R³SiX₃ (3)
[In formula (3), R³ represents an organic group, and X represents a hydrolyzable group, where the multiple X groups in the same molecule may be the same or different].
